(19) United States
(12) Patent Application Publication
(10) Pub. No.: US 2024/0402617 A1
(43) Pub. Date: Dec. 5, 2024

(54) SYSTEMS AND METHODS FOR GENERATING SEM-QUALITY METROLOGY DATA FROM OPTICAL METROLOGY DATA USING MACHINE LEARNING

(71) Applicant: ASML Netherlands B.V., Veldhoven (NL)

(72) Inventors: Spencer ALEXANDER, Clyde Hill, WA (US); Junru RUAN, Beaverton, OR (US); Haiyan LI, Hillsboro, OR (US); Nathan Richard KEECH, Hillsboro, OR (US); Huai-Ying CHIN, Hillsboro, OR (US)

(73) Assignee: ASML Netherlands B.V., Veldhoven (NL)

(21) Appl. No.: 18/799,534

(22) Filed: Aug. 9, 2024

Related U.S. Application Data
(63) Continuation of application No. PCT/EP2023/052123, filed on Jan. 30, 2023.
(60) Provisional application No. 63/308,672, filed on Feb. 10, 2022.

(51) Int. Cl. G03F 7/00

(52) U.S. Cl. CPC G03F 7/70655; G03F 7/7065; G03F 7/706841

(57) ABSTRACT

In some embodiments, one or more non-transitory, machine-readable medium has instructions thereon, the instructions when executed by a processor being configured to perform operations comprising obtaining scanning electron microscopy (SEM) metrology data for first areas on a training wafer, obtaining optical metrology data for second areas on the training wafer, and training a model, by using the SEM metrology data and the optical metrology data for the training wafer, to generate parameters for features on a production wafer based on optical metrology data for areas of the production wafer.

### CROSS-REFERENCE TO RELATED APPLICATIONS

This application claims priority of International application PCT/EP2023/052123, filed on 30 Jan. 2023, which claims priority of U.S. application 63/308,672, filed on 10 Feb. 2022. These applications are incorporated herein by reference in their entireties.

### TECHNICAL FIELD

The present disclosure relates generally to semiconductor fabrication metrology.

### BACKGROUND

In manufacturing processes of integrated circuits (ICs), unfinished or finished circuit components are inspected to ensure that they are manufactured according to design and are free of defects. Inspection systems utilizing optical microscopes or charged particle (e.g., electron) beam microscopes, such as a scanning electron microscope (SEM) can be employed. As the physical sizes of IC components continue to shrink, and their structures continue to become more complex, accuracy and throughput in defect detection and inspection become more important. The overall image quality depends on a combination of high secondary-electron and backscattered-electron signal detection efficiencies, among others. Backscattered electrons have higher emission energy to escape from deeper layers of a sample, and therefore, their detection may be desirable for imaging of complex structures such as buried layers, nodes, high-aspect-ratio trenches or holes of 3D NAND devices. For applications such as overlay metrology, it may be desirable to obtain high quality imaging and efficient collection of surface information from secondary electrons and buried layer information from backscattered electrons, simultaneously, highlighting a need for using multiple electron detectors in a SEM. Although multiple electron detectors in various structural arrangements may be used to maximize collection and detection efficiencies of secondary and backscattered electrons individually, the combined detection efficiencies remain low, and therefore, the image quality achieved may be inadequate for high accuracy and high throughput defect inspection and metrology of two-dimensional and three-dimensional structures.

In the context of semiconductor manufacture, semiconductor fabrication processes and structures are monitored via metrology. Improved metrology can lead to improved process performance and outcomes. Various solutions for metrology improvements have been proposed.

### SUMMARY

In some embodiments of the present disclosure, one or more non-transitory, machine-readable medium has instructions thereon, the instructions when executed by a processor being configured to perform operations comprising obtaining scanning electron microscopy (SEM) metrology data for first areas on a training wafer, obtaining optical metrology data for second areas on the training wafer, and training a model, by using the SEM metrology data and the optical metrology data for the training wafer, to generate parameters for features on a production wafer based on optical metrology data for areas of the production wafer.

In some embodiments, the operations further comprise obtaining optical metrology data for areas of the production wafer and determining feature parameters of the production wafer, based on the optical metrology data for the production wafer and the trained model.

In some embodiments, the operations further comprise retraining the model based on detection of a retraining trigger.

In some embodiments, detecting a wafer fabrication change comprises monitoring one or more performance indicators associated with wafer fabrication.

In some embodiments, the feature parameters comprise at least one of overlay, overlay error, critical dimension, critical dimension uniformity, edge placement error, focus, dose, local overlay, local overlay error, local critical dimension, local critical dimension uniformity, one or more feature dimensions, or a combination thereof.

In some embodiments of the present disclosure, one or more non-transitory, machine-readable medium has instructions thereon, the instructions when executed by a processor being configured to perform operations comprising obtaining optical metrology data for areas of a production wafer and determining parameters for features on the production wafer based on the optical metrology data and a trained model, wherein the parameters for features on the production wafer comprise pseudo-scanning-electron-microscopy (SEM) parameters.

In some embodiments, the model is generated by obtaining (SEM) metrology data for first areas on one or more training wafers, obtaining optical metrology data for second areas on the one or more training wafers, and training the model, by using the SEM metrology data and the optical metrology data, to generate parameters for features on the production wafer.

In some embodiments of the present disclosure, a processor and one or more non-transitory, machine-readable medium to as described in the previous embodiments.

In some embodiments of the present disclosure, a method comprising obtaining scanning electron microscopy (SEM) metrology data for first areas on one or more training wafers, obtaining optical metrology data for second areas on the one or more training wafers, and training a model, by using the SEM metrology data and the optical metrology data, to generate parameters for features on one or more production wafers based on optical metrology data for areas of the one or more production wafers.

In some embodiments, obtaining optical metrology data for areas of the one or more production wafers, and determining parameters for features on the one or more production wafers, based on the optical metrology data for the one or more production wafers and the trained model.

Other advantages of the embodiments of the present disclosure will become apparent from the following description taken in conjunction with the accompanying drawings wherein are set forth, by way of illustration and example, certain embodiments of the present disclosure.

### BRIEF DESCRIPTION OF THE DRAWINGS

FIG. 1 is a schematic diagram illustrating an exemplary electron beam inspection (EBI) system, consistent with embodiments of the present disclosure.

FIG. 2 is a schematic diagram illustrating an exemplary electron beam tool that can be a part of the exemplary electron beam inspection system of FIG. 1, consistent with embodiments of the present disclosure.

FIG. 3 is a schematic diagram of an exemplary charged-particle beam apparatus comprising a charged-particle detector, consistent with embodiments of the present disclosure.

FIG. 4 depicts a schematic overview of a lithographic apparatus, according to some embodiments of the present disclosure.

FIG. 5 depicts a schematic overview of a lithographic cell, according to some embodiments of the present disclosure.

FIG. 6 depicts a schematic representation of holistic lithography, representing a cooperation between three technologies to optimize semiconductor manufacturing, according to some embodiments of the present disclosure.

FIG. 7 illustrates an example metrology apparatus, such as a scatterometer, according to some embodiments of the present disclosure.

FIG. 8 illustrates a summary of operations of a present method for training a model to generate pseudo-scanning-electron-microscopy (SEM) metrology data based on optical metrology data, according to some embodiments of the present disclosure.

FIG. 9 illustrates an exemplary method for training a model to generate pseudo-SEM metrology data based on optical metrology data, according to some embodiments of the present disclosure.

FIG. 10 illustrates a summary of operations of a present method for determining pseudo-SEM metrology data based on optical metrology data, according to some embodiments of the present disclosure.

FIG. 11 illustrates a relationship between optical metrology data and optical-metrology-derived performance indicators, according to some embodiments of the present disclosure.

FIG. 12 illustrates a relationship between SEM metrology data and SEM-derived performance indicators, according to some embodiments of the present disclosure.

FIG. 13 illustrates a summary of operations of a present method for triggering retraining of the model, according to some embodiments of the present disclosure.

FIG. 14 illustrates an exemplary method for determination of feature parameters and, optionally, retraining of the model, according to some embodiments of the present disclosure.

FIG. 15 depicts a schematic representation of measurement areas on a wafer, according to some embodiments of the present disclosure.

FIG. 16 is a block diagram of an example computer system, according to some embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations. Instead, they are merely examples of apparatuses and methods consistent with aspects related to the disclosed embodiments as recited in the appended claims. For example, although some embodiments are described in the context of utilizing electron beams, the disclosure is not so limited. Other types of charged particle beams may be similarly applied. Furthermore, other imaging systems may be used, such as optical imaging, photo detection, x-ray detection, etc.

Electronic devices are constructed of circuits formed on a piece of silicon called a substrate. Many circuits may be formed together on the same piece of silicon and are called integrated circuits or ICs. The size of these circuits has decreased dramatically so that many more of them can fit on the substrate. For example, an IC chip in a smart phone can be as small as a thumbnail and yet may include over 2 billion transistors, the size of each transistor being less than 1/1000th the size of a human hair.

Making these extremely small ICs is a complex, time-consuming, and expensive process, often involving hundreds of individual steps. Errors in even one step have the potential to result in defects in the finished IC, thereby rendering it useless. Thus, one goal of the manufacturing process is to avoid such defects to maximize the number of functional ICs made in the process, that is, to improve the overall yield of the process.

One component of improving yield is monitoring the chip making process to ensure that it is producing a sufficient number of functional integrated circuits. One way to monitor the process is to inspect the chip circuit structures at various stages of their formation. Inspection can be carried out using a scanning electron microscope (SEM). An SEM can be used to image these extremely small structures, in effect, taking a “picture” of the structures. The image can be used to determine if the structure was formed properly and also if it was formed in the proper location. If the structure is defective, then the process can be adjusted so the defect is less likely to recur. It may be desirable to have higher throughput for defect detection and inspection processes to meet the requirements of IC manufacturers.

Inspection can also be carried out using one or more optical methods. Optical methods can include optical microscopy, including optical imaging. Optical methods of inspection can also include one or more measure of alignment, such as diffraction-based overlay measurements. Optical methods of inspection can be part of a lithographic process for patterning the device.

A lithographic projection apparatus can be used, for example, in the manufacture of integrated circuits (ICs). A patterning device (e.g., a mask) may include or provide a pattern corresponding to an individual layer of the IC (“design layout”), and this pattern can be transferred onto a target portion (e.g. comprising one or more dies) on a substrate (e.g., silicon wafer) that has been coated with a layer of radiation-sensitive material (“resist”), by methods such as irradiating the target portion through the pattern on the patterning device. In general, a single substrate contains a plurality of adjacent target portions to which the pattern is transferred successively by the lithographic projection apparatus, one target portion at a time. Different portions of the pattern on the patterning device are transferred to one target portion progressively. More information with regard to lithographic devices can be found in, for example, U.S. Pat. No. 6,046,792, incorporated herein by reference.

Prior to transferring the pattern from the patterning device to the substrate, the substrate may undergo various procedures, such as priming, resist coating and a soft bake. After exposure, the substrate may be subjected to other procedures (“post-exposure procedures”), such as a post-exposure bake (PEB), development, a hard bake and measurement/inspection of the transferred pattern. This array of procedures is used as a basis to make an individual layer of a device, e.g., an IC. The substrate may then undergo various processes such as etching, ion-implantation (doping), metallization, oxidation, chemo-mechanical polishing, etc., all intended to finish the individual layer of the device. If several layers are required in the device, then the whole procedure, or a variant thereof, is repeated for each layer. Eventually, a device will be present in each target portion on the substrate. These devices are then separated from one another by a technique such as dicing or sawing, such that the individual devices can be mounted on a carrier, connected to pins, etc.

Manufacturing devices, such as semiconductor devices, typically involves processing a substrate (e.g., a semiconductor wafer) using a number of fabrication processes to form various features and multiple layers of the devices. Such layers and features are typically manufactured and processed using, e.g., deposition, lithography, etch, chemical-mechanical polishing, and ion implantation. Multiple devices may be fabricated on a plurality of dies on a substrate and then separated into individual devices. This device manufacturing process may be considered a patterning process. A patterning process involves a patterning step, such as optical and/or nanoimprint lithography using a patterning device in a lithographic apparatus, to transfer a pattern on the patterning device to a substrate and typically, but optionally, involves one or more related pattern processing steps, such as resist development by a development apparatus, baking of the substrate using a bake tool, etching using the pattern using an etch apparatus, etc.

Lithography is a central step in the manufacturing of device such as ICs, where patterns formed on substrates define functional elements of the devices, such as microprocessors, memory chips, etc. Similar lithographic techniques are also used in the formation of flat panel displays, micro-electromechanical systems (MEMS) and other devices.

As semiconductor manufacturing processes continue to advance, the dimensions of functional elements have continually been reduced. At the same time, the number of functional elements, such as transistors, per device has been steadily increasing, following a trend commonly referred to as “Moore's law.” At the current state of technology, layers of devices are manufactured using lithographic projection apparatuses that project a design layout onto a substrate using illumination from a deep-ultraviolet illumination source, creating individual functional elements having dimensions well below 100 nm, i.e., less than half the wavelength of the radiation from the illumination source (e.g., a 193 nm illumination source).

This process in which features with dimensions smaller than the classical resolution limit of a lithographic projection apparatus are printed, is commonly known as low-k1 lithography, according to the resolution formula CD=k1×λ/NA, where λ is the wavelength of radiation employed (currently in most cases 248 nm or 193 nm), NA is the numerical aperture of projection optics in the lithographic projection apparatus, CD is the “critical dimension”—generally the smallest feature size printed—and k1 is an empirical resolution factor. In general, the smaller k1 the more difficult it becomes to reproduce a pattern on the substrate that resembles the shape and dimensions planned by a designer in order to achieve particular electrical functionality and performance. To overcome these difficulties, sophisticated fine-tuning steps are applied to the lithographic projection apparatus, the design layout, or the patterning device. These include, for example, but not limited to, optimization of NA and optical coherence settings, customized illumination schemes, use of phase shifting patterning devices, optical proximity correction (OPC, sometimes also referred to as “optical and process correction”) in the design layout, source mask optimization (SMO), or other methods generally defined as “resolution enhancement techniques” (RET). The term “projection optics” as used herein should be broadly interpreted as encompassing various types of optical systems, including refractive optics, reflective optics, apertures and catadioptric optics, for example. The term “projection optics” may also include components operating according to any of these design types for directing, shaping or controlling the projection beam of radiation, collectively or singularly. The term “projection optics” may include any optical component in the lithographic projection apparatus, no matter where the optical component is located on an optical path of the lithographic projection apparatus. Projection optics may include optical components for shaping, adjusting and/or projecting radiation from the source before the radiation passes the patterning device, and/or optical components for shaping, adjusting and/or projecting the radiation after the radiation passes the patterning device. The projection optics generally exclude the source and the patterning device.

Optical inspection and SEM inspection have different strengths and weaknesses. Improved overall inspection and monitoring can be achieved by utilizing the strengths of both optical inspection, including speed, and SEM inspection, including accuracy. A model can be trained to relate optical inspection parameters and SEM inspection parameters in order to harness the strengths of the accuracy and precision of SEM inspection and the strengths of speed and non-destructiveness of optical inspection. A model can be trained to generate SEM-like inspection parameters (i.e., “pseudo-SEM performance indicators” or other parameters) based on optical inspection parameters (i.e., “optical metrology performance indicators” or other parameters). The trained model can then be used to generate SEM-like inspection parameters and the fabrication process can be monitored at various points based on the SEM-like inspection parameters. Based on periodic monitoring of SEM inspection parameters, the accuracy of the model can be checked and adjusted and used for process control.

Although specific reference may be made in this text to the manufacture of ICs, it should be explicitly understood that the description herein has many other possible applications. For example, it may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “reticle,” “wafer,” or “die” in this text should be considered as interchangeable with the more general terms “mask,” “substrate,” and “target portion,” respectively.

Relative dimensions of components in drawings may be exaggerated for clarity. Within the following description of drawings, the same or like reference numbers refer to the same or like components or entities, and only the differences with respect to the individual embodiments are described. As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

A patterning device can comprise, or can form, one or more patterns. The pattern can be generated utilizing CAD (computer-aided design) programs, based on a pattern or design layout, this process often being referred to as EDA (electronic design automation). Most CAD programs follow a set of predetermined design rules in order to create functional design layouts/patterning devices. These rules are set by processing and design limitations. For example, design rules define the space tolerance between devices (such as gates, capacitors, etc.) or interconnect lines, so as to ensure that the devices or lines do not interact with one another in an undesirable way. The design rules may include and/or specify specific parameters, limits on and/or ranges for parameters, and/or other information. One or more of the design rule limitations and/or parameters may be referred to as a “critical dimension” (CD). A critical dimension of a device can be defined as the smallest width of a line or hole or the smallest space between two lines or two holes, or other features. Thus, the CD determines the overall size and density of the designed device. One of the goals in device fabrication is to faithfully reproduce the original design intent on the substrate (via the patterning device).

The term “mask” or “patterning device” as employed in this text may be broadly interpreted as referring to a generic semiconductor patterning device that can be used to endow an incoming radiation beam with a patterned cross-section, corresponding to a pattern that is to be created in a target portion of the substrate; the term “light valve” can also be used in this context. Besides the classic mask (transmissive or reflective; binary, phase-shifting, hybrid, etc.), examples of other such patterning devices include a programmable mirror array and a programmable LCD array.

As used herein, the term “patterning process” generally means a process that creates an etched substrate by the application of specified patterns of light as part of a lithography process. However, “patterning process” can also include (e.g., plasma) etching, as many of the features described herein can provide benefits to forming printed patterns using etch (e.g., plasma) processing.

As used herein, the term “pattern” means an idealized pattern that is to be etched on a substrate (e.g., wafer)—e.g., based on the design layout described above. A pattern may comprise, for example, various shape(s), arrangement(s) of features, contour(s), etc.

As used herein, a “printed pattern” means the physical pattern on a substrate that was etched based on a target pattern. The printed pattern can include, for example, troughs, channels, depressions, edges, or other two- and three-dimensional features resulting from a lithography process.

As used herein, the term “prediction model,” “process model,” “electronic model,” and/or “simulation model” (which may be used interchangeably) means a model that includes one or more models that simulate a patterning process. For example, a model can include an optical model (e.g., that models a lens system/projection system used to deliver light in a lithography process and may include modelling the final optical image of light that goes onto a photoresist), a resist model (e.g., that models physical effects of the resist, such as chemical effects due to the light), an OPC model (e.g., that can be used to make target patterns and may include sub-resolution resist features (SRAFs), etc.), an etch (or etch bias) model (e.g., that simulates the physical effects of an etching process on a printed wafer pattern), a source mask optimization (SMO) model, and/or other models.

As used herein, the term “calibrating” means to modify (e.g., improve or tune) and/or validate a model, an algorithm, and/or other components of a present system and/or method.

A patterning system may be a system comprising any or all of the components described above, plus other components configured to performing any or all of the operations associated with these components. A patterning system may include a lithographic projection apparatus, a scanner, systems configured to apply and/or remove resist, etching systems, and/or other systems, for example.

As used herein, the term “diffraction” refers to the behavior of a beam of light or other electromagnetic radiation when encountering an aperture or series of apertures, including a periodic structure or grating. “Diffraction” can include both constructive and destructive interference, including scattering effects and interferometry. As used herein, a “grating” is a periodic structure, which can be one-dimensional (i.e., comprised of posts of dots), two-dimensional, or three-dimensional, and which causes optical interference, scattering, or diffraction. A “grating” can be a diffraction grating.

As used herein, “fabrication” refers to one or more of the steps of manufacture which take a bare semiconductor wafer to a finished electronic (or electro-optical) device. Fabrication can include steps of deposition (e.g., metal deposition), oxide growth, ion implantation, lithography, etch, cleaning, etc.

As used herein, “metrology” refers to a system of one or more measurements or an apparatus for performing the same. Metrology can include comparing of a measurement to a standard and quantifying one or more material and/or feature parameters or process steps. Metrology can refer to general data gathering and accumulation steps, including the measurement devices which perform measurements or receive input which correlates to measurements. Example metrology apparatus include scanning electron microscopes (SEM), optical metrology tools, such as diffraction-based overlay measurement apparatuses, defect measurement devices, such as surface profilometers, etc.

As used herein, “performance indicator” refers to a performance metric which is measured, tracked and/or evaluated in order to infer information about performance. A performance indicator can be used to make one or more decisions about a process. A performance indicator can indicate that a process is proceeding within expected natural variations or that a process has experienced a change. A performance indicator can be quantitative or qualitative. A performance indicator may be a key performance indicator (KPI). Alternatively, a performance indicator may not be a KPI or may not be a KPI currently but may have the capability to become a KPI if key utility is determined.

As used herein, “SEM-derived performance indicator” refers to a performance indicator determined or derived based at least in part on SEM metrology data.

As used herein, “optical-metrology derived performance indicator” refers to a performance indicator determined or derived based at least in part on optical metrology data.

As used herein, “continuous learning” refers to a type of training and updating based on a continuous input of data. A model, which can be a machine learning model, can be updated based on continuous learning. Continuous learning can include monitoring of the applicability of the model to the continuous input of data and detect if the model no longer applies or correctly models the data. Continuous learning can comprise retraining and/or updating of the model based on new or recent data, which allows the model to continually shift to reflect a changing process. Continuous learning can instead or additionally include routine or regular updating or retraining of the model, even if misalignment between the data and the model is not detected.

As used herein, “high-volume manufacturing” refers to mass production of a manufactured product in a limited time. As used herein, “high-volume manufacturing” refers more specifically to fabrication of semiconductor devices where the product and process are well characterized and standardized, as opposed to research, calibration, test, qualification, etc. processes which may not be well-characterized and may experience changes in recipes, materials, variations, etc.

As used herein, “gold standard” refers to a process which generates the best or more accurate results. For processes with similar accuracy, the process with the most precise results or the most significant figures can be the gold standard. For example, in metrology a gold standard is the measurement, regardless of time, cost, and/or destructiveness, which produces the measurement closest to the true value of a parameter. SEM metrology is considered a gold standard for measurement of feature dimensions.

As used herein, a “process of record” is a process used in high volume manufacturing to perform a certain step or measurement. The process of record is selected by balancing time, cost, accuracy, and quality of results. The process of record need not be the quickest, cheapest, or best at a particular step or measurement, but instead is selected to provide results which are good enough without sacrificing time and/or money. The process of record may not be the gold standard.

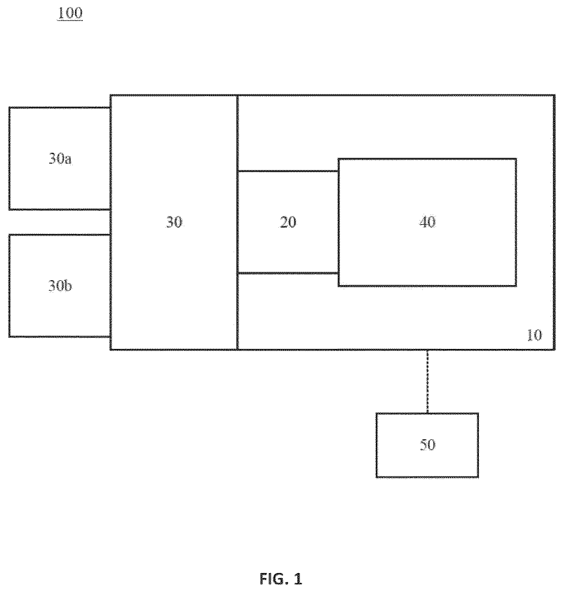

Reference is now made to FIG. 1, which illustrates an exemplary electron beam inspection (EBI) system 100 consistent with embodiments of the present disclosure. As shown in FIG. 1, charged particle beam inspection system 100 includes a main chamber 10, a load-lock chamber 20, an electron beam tool 40, and an equipment front end module (EFEM) 30. Electron beam tool 40 is located within main chamber 10. While the description and drawings are directed to an electron beam, it is appreciated that the embodiments are not used to limit the present disclosure to specific charged particles.

EFEM 30 includes a first loading port 30a and a second loading port 30b. EFEM 30 may include additional loading port(s). First loading port 30a and second loading port 30b receive wafer front opening unified pods (FOUPs) that contain wafers (e.g., semiconductor wafers or wafers made of other material(s)) or samples to be inspected (wafers and samples are collectively referred to as “wafers” hereafter). One or more robot arms (not shown) in EFEM 30 transport the wafers to load-lock chamber 20.

Load-lock chamber 20 is connected to a load/lock vacuum pump system (not shown), which removes gas molecules in load-lock chamber 20 to reach a first pressure below the atmospheric pressure. After reaching the first pressure, one or more robot arms (not shown) transport the wafer from load-lock chamber 20 to main chamber 10. Main chamber 10 is connected to a main chamber vacuum pump system (not shown), which removes gas molecules in main chamber 10 to reach a second pressure below the first pressure. After reaching the second pressure, the wafer is subject to inspection by electron beam tool 40. In some embodiments, electron beam tool 40 may comprise a single-beam inspection tool.

Controller 50 may be electronically connected to electron beam tool 40 and may be electronically connected to other components as well. Controller 50 may be a computer configured to execute various controls of charged particle beam inspection system 100. Controller 50 may also include processing circuitry configured to execute various signal and image processing functions. While controller 50 is shown in FIG. 1 as being outside of the structure that includes main chamber 10, load-lock chamber 20, and EFEM 30, it is appreciated that controller 50 can be part of the structure.

While the present disclosure provides examples of main chamber 10 housing an electron beam inspection system, it should be noted that aspects of the disclosure in their broadest sense, are not limited to a chamber housing an electron beam inspection system. Rather, it is appreciated that the foregoing principles may be applied to other chambers as well, such as a chamber of a deep ultraviolet (DUV) lithography or an extreme ultraviolet (EUV) lithography system.

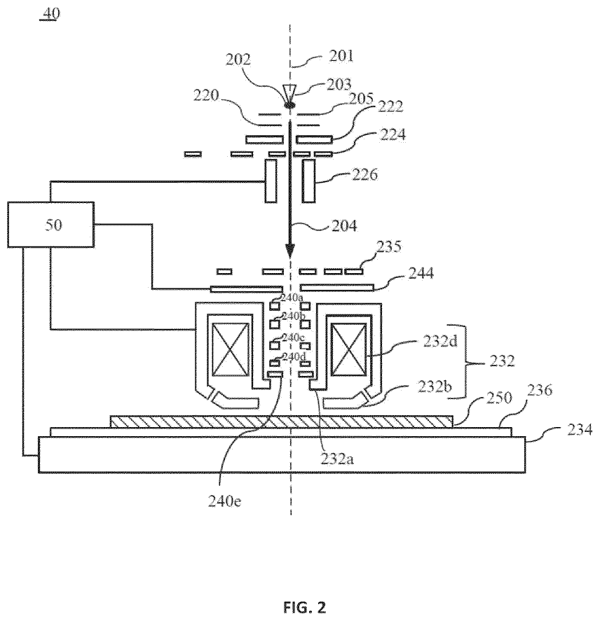

Reference is now made to FIG. 2, which illustrates a schematic diagram illustrating an exemplary configuration of electron beam tool 40 that can be a part of the exemplary charged particle beam inspection system 100 of FIG. 1, consistent with embodiments of the present disclosure. Electron beam tool 40 (also referred to herein as apparatus 40) may comprise an electron emitter, which may comprise a cathode 203, an extractor electrode 205, a gun aperture 220, and an anode 222. Electron beam tool 40 may further include a Coulomb aperture array 224, a condenser lens 226, a beam-limiting aperture array 235, an objective lens assembly 232, and an electron detector 244. Electron beam tool 40 may further include a sample holder 236 supported by motorized stage 234 to hold a sample 250 to be inspected. It is to be appreciated that other relevant components may be added or omitted, as needed.

In some embodiments, an electron emitter may include cathode 203 and anode 222, wherein primary electrons can be emitted from the cathode and extracted or accelerated to form a primary electron beam 204 that forms a primary beam crossover 202. Primary electron beam 204 can be visualized as being emitted from primary beam crossover 202.

In some embodiments, the electron emitter, condenser lens 226, objective lens assembly 232, beam-limiting aperture array 235, and electron detector 244 may be aligned with a primary optical axis 201 of apparatus 40. In some embodiments, electron detector 244 may be placed off primary optical axis 201, along a secondary optical axis (not shown).

Objective lens assembly 232, in some embodiments, may comprise a modified swing objective retarding immersion lens (SORIL), which includes a pole piece 232a, a control electrode 232b, a beam manipulator assembly comprising deflectors 240a, 240b, 240d, and 240e, and an exciting coil 232d. In a general imaging process, primary electron beam 204 emanating from the tip of cathode 203 is accelerated by an accelerating voltage applied to anode 222. A portion of primary electron beam 204 passes through gun aperture 220, and an aperture of Coulomb aperture array 224, and is focused by condenser lens 226 so as to fully or partially pass through an aperture of beam-limiting aperture array 235. The electrons passing through the aperture of beam-limiting aperture array 235 may be focused to form a probe spot on the surface of sample 250 by the modified SORIL lens and deflected to scan the surface of sample 250 by one or more deflectors of the beam manipulator assembly. Secondary electrons emanated from the sample surface may be collected by electron detector 244 to form an image of the scanned area of interest.

In objective lens assembly 232, exciting coil 232d and pole piece 232a may generate a magnetic field. A part of sample 250 being scanned by primary electron beam 204 can be immersed in the magnetic field and can be electrically charged, which, in turn, creates an electric field. The electric field may reduce the energy of impinging primary electron beam 204 near and on the surface of sample 250. Control electrode 232b, being electrically isolated from pole piece 232a, may control, for example, an electric field above and on sample 250 to reduce aberrations of objective lens assembly 232, to adjust the focusing of signal electron beams for high detection efficiency, or to avoid arcing to protect the sample. One or more deflectors of the beam manipulator assembly may deflect primary electron beam 204 to facilitate beam scanning on sample 250. For example, in a scanning process, deflectors 240a, 240b, 240d, and 240e can be controlled to deflect primary electron beam 204, onto different locations of top surface of sample 250 at different time points, to provide data for image reconstruction for different parts of sample 250. It is noted that the order of 240a-e may be different in different embodiments.

Backscattered electrons (BSEs) and secondary electrons (SEs) can be emitted from the part of sample 250 upon receiving primary electron beam 204. A beam separator 240c can direct the secondary or scattered electron beam(s), comprising backscattered and secondary electrons, to a sensor surface of electron detector 244. The detected secondary electron beams can form corresponding beam spots on the sensor surface of electron detector 244. Electron detector 244 can generate signals (e.g., voltages, currents) that represent the intensities of the received secondary electron beam spots, and provide the signals to a processing system, such as controller 50. The intensity of secondary or backscattered electron beams, and the resultant secondary electron beam spots, can vary according to the external or internal structure of sample 250. Moreover, as discussed above, primary electron beam 204 can be deflected onto different locations of the top surface of sample 250 to generate secondary or scattered electron beams (and the resultant beam spots) of different intensities. Therefore, by mapping the intensities of the secondary electron beam spots with the locations of sample 250, the processing system can reconstruct an image that reflects the internal or external structures of sample 250, which can comprise a wafer sample.

In some embodiments, controller 50 may comprise an image processing system that includes an image acquirer (not shown) and a storage (not shown). The image acquirer may comprise one or more processors. For example, the image acquirer may comprise a computer, server, mainframe host, terminals, personal computer, any kind of mobile computing devices, and the like, or a combination thereof. The image acquirer may be communicatively coupled to electron detector 244 of apparatus 40 through a medium such as an electrical conductor, optical fiber cable, portable storage media, IR, Bluetooth, internet, wireless network, wireless radio, among others, or a combination thereof. In some embodiments, the image acquirer may receive a signal from electron detector 244 and may construct an image. The image acquirer may thus acquire images of regions of sample 250. The image acquirer may also perform various post-processing functions, such as generating contours, superimposing indicators on an acquired image, and the like. The image acquirer may be configured to perform adjustments of brightness and contrast, etc. of acquired images. In some embodiments, the storage may be a storage medium such as a hard disk, flash drive, cloud storage, random access memory (RAM), other types of computer readable memory, and the like. The storage may be coupled with the image acquirer and may be used for saving scanned raw image data as original images, and post-processed images.

In some embodiments, controller 50 may include measurement circuitries (e.g., analog-to-digital converters) to obtain a distribution of the detected secondary electrons and backscattered electrons. The electron distribution data collected during a detection time window, in combination with corresponding scan path data of a primary electron beam 204 incident on the sample (e.g., a wafer) surface, can be used to reconstruct images of the wafer structures under inspection. The reconstructed images can be used to reveal various features of the internal or external structures of sample 250, and thereby can be used to reveal any defects that may exist in the wafer.

In some embodiments, controller 50 may control motorized stage 234 to move sample 250 during inspection. In some embodiments, controller 50 may enable motorized stage 234 to move sample 250 in a direction continuously at a constant speed. In other embodiments, controller 50 may enable motorized stage 234 to change the speed of the movement of sample 250 over time depending on the steps of scanning process.

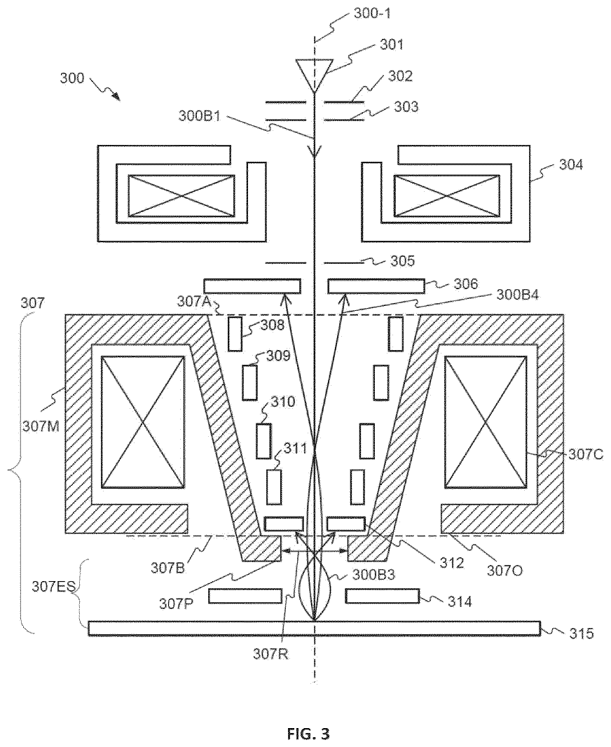

As is commonly known in the art, interaction of charged particles, such as electrons of a primary electron beam with a sample (e.g., sample 315 of FIG. 3, discussed later), may generate signal electrons containing compositional and topographical information about the probed regions of the sample. Secondary electrons (SEs) may be identified as signal electrons with low emission energies, and backscattered electrons (BSEs) may be identified as signal electrons with high emission energies. Because of their low emission energy, an objective lens assembly may direct the SEs along electron paths and focus the SEs on a detection surface of in-lens electron detector placed inside the SEM column. BSEs traveling along electron paths may be detected by the in-lens electron detector as well. In some cases, BSEs with large emission angles, however, may be detected using additional electron detectors, such as a backscattered electron detector, or remain undetected, resulting in loss of sample information needed to inspect a sample or measure critical dimensions.

Detection and inspection of some defects in semiconductor fabrication processes, such as buried particles during photolithography, metal deposition, dry etching, or wet etching, among others, may benefit from inspection of surface features as well as compositional analysis of the defect particle. In such scenarios, information obtained from secondary electron detectors and backscattered electron detectors to identify the defect(s), analyze the composition of the defect(s), and adjust process parameters based on the obtained information, among others, may be desirable for a user.

The emission of SEs and BSEs obeys Lambert's law and has a large energy spread. SEs and BSEs are generated upon interaction of primary electron beam with the sample, from different depths of the sample and have different emission energies. For example, secondary electrons originate from the surface and may have an emission energy ≤50 eV, depending on the sample material, or volume of interaction, among others. SEs are useful in providing information about surface features or surface geometries. BSEs, on the other hand, are generated by predominantly elastic scattering events of the incident electrons of the primary electron beam and typically have higher emission energies in comparison to SEs, in a range from 50 eV to approximately the landing energy of the incident electrons, and provide compositional and contrast information of the material being inspected. The number of BSEs generated may depend on factors including, but are not limited to, atomic number of the material in the sample, acceleration voltage of primary electron beam, among others.

Based on the difference in emission energy, or emission angle, among others, SEs and BSEs may be separately detected using separate electron detectors, segmented electron detectors, energy filters, and the like. For example, an in-lens electron detector may be configured as a segmented detector comprising multiple segments arranged in a two-dimensional or a three-dimensional arrangement. In some cases, the segments of in-lens electron detector may be arranged radially, circumferentially, or azimuthally around a primary optical axis (e.g., primary optical axis 300-1 of FIG. 3).

Reference is now made to FIG. 3, which illustrates a schematic diagram of an exemplary charged-particle beam apparatus 300 (also referred to as apparatus 300), consistent with embodiments of the present disclosure. Apparatus 300 can be a part of the exemplary electron beam tool of FIG. 2 and/or a part of the exemplary charge particle beam inspection system 100 of FIG. 1. Apparatus 300 may comprise a charged-particle source such as, an electron source configured to emit primary electrons from a cathode 301 and extracted using an extractor electrode 302 to form a primary electron beam 300B1 along a primary optical axis 300-1. Apparatus 300 may further comprise an anode 303, a condenser lens 304, a beam-limiting aperture array 305, signal electron detectors 306 and 312, a compound objective lens 307, a scanning deflection unit comprising primary electron beam deflectors 308, 309, 310, and 311, and a control electrode 314. In the context of this disclosure, one or both of signal electron detectors 306 and 312 may be in-lens electron detectors located inside the electron-optical column of a SEM and may be arranged rotationally symmetric around primary optical axis 300-1. In some embodiments, signal electron detector 312 may be referred to as a first electron detector, and signal electron detector 306 may be referred to as through-the-lens detector, immersion lens detector, upper detector, or second electron detector. It is to be appreciated that relevant components may be added, omitted, or reordered, as appropriate.

An electron source (not shown) may include a thermionic source configured to emit electrons upon being supplied thermal energy to overcome the work function of the source, a field emission source configured to emit electrons upon being exposed to a large electrostatic field, etc. In the case of a field emission source, the electron source may be electrically connected to a controller, such as controller 50 of FIG. 1, configured to apply and adjust a voltage signal based on a desired landing energy, sample analysis, source characteristics, among others. Extractor electrode 302 may be configured to extract or accelerate electrons emitted from a field emission gun, for example, to form primary electron beam 300B1 that forms a virtual or a real primary beam crossover (not illustrated) along primary optical axis 300-1. Primary electron beam 300B1 may be visualized as being emitted from the primary beam crossover. In some embodiments, the controller may be configured to apply and adjust a voltage signal to extractor electrode 302 to extract or accelerate electrons generated from electron source. An amplitude of the voltage signal applied to extractor electrode 302 may be different from the amplitude of the voltage signal applied to cathode 301. In some embodiments, the difference between the amplitudes of the voltage signal applied to extractor electrode 302 and to cathode 301 may be configured to accelerate the electrons downstream along primary optical axis 300-1 while maintaining the stability of the electron source. As used in the context of this disclosure, “downstream” refers to a direction along the path of primary electron beam 300B1 starting from the electron source towards sample 315. With reference to positioning of an element of a charged-particle beam apparatus (e.g., apparatus 300 of FIG. 3), “downstream” may refer to a position of an element located below or after another element, along the path of primary electron beam starting from the electron source, and “immediately downstream” refers to a position of a second element below or after a first element along the path of primary electron beam 300B1 such that there are no other active elements between the first and the second element. For example, as illustrated in FIG. 3, signal electron detector 306 may be positioned immediately downstream of beam-limiting aperture array 305 such that there are no other optical or electron-optical elements placed between beam-limiting aperture array 305 and electron detector 306. As used in the context of this disclosure, “upstream” may refer to a position of an element located above or before another element, along the path of primary electron beam starting from the electron source, and “immediately upstream” refers to a position of a second element above or before a first element along the path of primary electron beam 300B1 such that there are no other active elements between the first and the second element. As used herein, “active element” may refer to any element or component, the presence of which may modify the electromagnetic field between the first and the second element, either by generating an electric field, a magnetic field, or an electromagnetic field.

Apparatus 300 may comprise condenser lens 304 configured to receive a portion of or a substantial portion of primary electron beam 300B1 and to focus primary electron beam 300B1 on beam-limiting aperture array 305. Condenser lens 304 may be substantially similar to condenser lens 226 of FIG. 2 and may perform substantially similar functions. Although shown as a magnetic lens in FIG. 3, condenser lens 304 may be an electrostatic, a magnetic, an electromagnetic, or a compound electromagnetic lens, among others. Condenser lens 304 may be electrically coupled with a controller, such as controller 50 of FIG. 2. The controller may apply an electrical excitation signal to condenser lens 304 to adjust the focusing power of condenser lens 304 based on factors including operation mode, application, desired analysis, sample material being inspected, among others.

Apparatus 300 may further comprise beam-limiting aperture array 305 configured to limit beam current of primary electron beam 300B1 passing through one of a plurality of beam-limiting apertures of beam-limiting aperture array 305. Although only one beam-limiting aperture is illustrated in FIG. 3, beam-limiting aperture array 305 may include any number of apertures having uniform or non-uniform aperture size, cross-section, or pitch. In some embodiments, beam-limiting aperture array 305 may be disposed downstream of condenser lens 304 or immediately downstream of condenser lens 304 (as illustrated in FIG. 3) and substantially perpendicular to primary optical axis 300-1. In some embodiments, beam-limiting aperture array 305 may be configured as an electrically conducting structure comprising a plurality of beam-limiting apertures. Beam-limiting aperture array 305 may be electrically connected via a connector (not illustrated) with controller 50, which may be configured to instruct that a voltage be supplied to beam-limiting aperture array 305. The supplied voltage may be a reference voltage such as, for example, ground potential. The controller may also be configured to maintain or adjust the supplied voltage. Controller 50 may be configured to adjust the position of beam-limiting aperture array 305.

Apparatus 300 may comprise one or more signal electron detectors 306 and 312. Signal electron detectors 306 and 312 may be configured to detect substantially all secondary electrons and a portion of backscattered electrons based on the emission energy, emission polar angle, emission azimuthal angle of the backscattered electrons, among others. In some embodiments, signal electron detectors 306 and 312 may be configured to detect secondary electrons, backscattered electrons, or auger electrons. Signal electron detector 312 may be disposed downstream of signal electron detector 306. In some embodiments, signal electron detector 312 may be disposed downstream or immediately downstream of primary electron beam deflector 311. Signal electrons having low emission energy (typically ≤50 eV) or small emission polar angles, emitted from sample 315 may comprise secondary electron beam(s) 300B4, and signal electrons having high emission energy (typically >50 eV) and medium emission polar angles may comprise backscattered electron beam(s) 300B3. In some embodiments, 300B4 may comprise secondary electrons, low-energy backscattered electrons, or high-energy backscattered electrons with small emission polar angles. It is appreciated that although not illustrated, a portion of backscattered electrons may be detected by signal electron detector 306, and a portion of secondary electrons may be detected by signal electron detector 312. In overlay metrology and inspection applications, signal electron detector 306 may be useful to detect secondary electrons generated from a surface layer and backscattered electrons generated from the underlying deeper layers, such as deep trenches or high aspect-ratio holes.

Apparatus 300 may further include compound objective lens 307 configured to focus primary electron beam 300B1 on a surface of sample 315. The controller may apply an electrical excitation signal to the coils 307C of compound objective lens 307 to adjust the focusing power of compound objective lens 307 based on factors including primary beam energy, application need, desired analysis, sample material being inspected, among others. Compound objective lens 307 may be further configured to focus signal electrons, such as secondary electrons having low emission energies, or backscattered electrons having high emission energies, on a detection surface of a signal electron detector (e.g., in-lens signal electron detector 306 or detector 312). Compound objective lens 307 may be substantially similar to or perform substantially similar functions as objective lens assembly 232 of FIG. 2. In some embodiments, compound objective lens 307 may comprise an electromagnetic lens including a magnetic lens 307M, and an electrostatic lens 307ES formed by control electrode 314, polepiece 307P, and sample 315.

As used herein, a compound objective lens is an objective lens producing overlapping magnetic and electrostatic fields, both in the vicinity of the sample for focusing the primary electron beam. In this disclosure, though condenser lens 304 may also be a magnetic lens, a reference to a magnetic lens, such as 307M, refers to an objective magnetic lens, and a reference to an electrostatic lens, such as 307ES, refers to an objective electrostatic lens. As illustrated in FIG. 3, magnetic lens 307M and electrostatic lens 307ES, working in unison, for example, to focus primary electron beam 300B1 on sample 315, may form compound objective lens 307. The lens body of magnetic lens 307M and coil 307C may produce the magnetic field, while the electrostatic field may be produced by creating a potential difference, for example, between sample 315, and polepiece 307P. In some embodiments, control electrode 314 or other electrodes located between polepiece 307P and sample 315, may also be a part of electrostatic lens 307ES.

In some embodiments, magnetic lens 307M may comprise a cavity defined by the space between imaginary planes 307A and 307B. It is to be appreciated that imaginary planes 307A and 307B, marked as broken lines in FIG. 3, are visual aids for illustrative purposes only. Imaginary plane 307A, located closer to condenser lens 304, may define the upper boundary of the cavity, and imaginary plane 307B, located closer to sample 315, may define the lower boundary of the cavity of magnetic lens 307M. As used herein, the “cavity” of the magnetic lens refers to space defined by the element of the magnetic lens configured to allow passage of the primary electron beam, wherein the space is rotationally symmetric around the primary optical axis. The term “within the cavity of magnetic lens” or “inside the cavity of the magnetic lens” refers to the space bound within the imaginary planes 307A and 307B and the internal surface of the magnetic lens 307M directly exposed to the primary electron beam. Planes 307A and 307B may be substantially perpendicular to primary optical axis 300-1. Although FIG. 3 illustrates a conical cavity, the cross-section of the cavity may be cylindrical, conical, staggered cylindrical, staggered conical, or any suitable cross-section.

Apparatus 300 may further include a scanning deflection unit comprising primary electron beam deflectors 308, 309, 310, and 311, configured to dynamically deflect primary electron beam 300B1 on a surface of sample 315. In some embodiments, scanning deflection unit comprising primary electron beam deflectors 308, 309, 310, and 311 may be referred to as a beam manipulator or a beam manipulator assembly. The dynamic deflection of primary electron beam 300B1 may cause a desired area or a desired region of interest of sample 315 to be scanned, for example in a raster scan pattern, to generate SEs and BSEs for sample inspection. One or more primary electron beam deflectors 308, 309, 310, and 311 may be configured to deflect primary electron beam 300B1 in X-axis or Y-axis, or a combination of X- and Y-axes. As used herein, X-axis and Y-axis form Cartesian coordinates, and primary electron beam 300B1 propagates along Z-axis or primary optical axis 300-1.

Electrons are negatively charged particles and travel through the electron-optical column and may do so at high energy and high speeds. One way to deflect the electrons is to pass them through an electric field or a magnetic field generated, for example, by a pair of plates held at two different potentials, or passing current through deflection coils, among other techniques. Varying the electric field or the magnetic field across a deflector (e.g., primary electron beam deflectors 308, 309, 310, and 311 of FIG. 3) may vary the deflection angle of electrons in primary electron beam 300B1 based on factors including, but are not limited to, electron energy, magnitude of the electric field applied, dimensions of deflectors, among others.

In some embodiments, one or more primary electron beam deflectors 308, 309, 310, and 311 may be located within the cavity of magnetic lens 307M. As illustrated in FIG. 3, all primary electron beam deflectors 308, 309, 310, and 311, in their entirety, may be located within the cavity of magnetic lens 307M. In some embodiments, at least one primary electron beam deflector, in its entirety, may be located within the cavity of magnetic lens 307M. In some embodiments, a substantial portion of the magnetic field generated by passing electrical current through coil 307C may be present in magnetic lens 307M such that each deflector is located inside the magnetic field lines of magnetic lens 307M or is influenced by the magnetic field of magnetic lens 307M. In such a scenario, sample 315 may be considered to be outside the magnetic field lines and may not be influenced by the magnetic field of magnetic lens 307M. A beam deflector (e.g., primary electron beam deflector 308 of FIG. 3) may be disposed circumferentially along the inner surface of magnetic lens 307M. One or more primary electron beam deflectors may be placed between signal electron detectors 306 and 312. In some embodiments, all primary electron beam deflectors may be placed between signal electron detectors 306 and 312.

As disclosed herein, a polepiece of a magnetic lens (e.g., magnetic lens 307M) is a piece of magnetic material near the magnetic poles of a magnetic lens, while a magnetic pole is the end of the magnetic material where the external magnetic field is the strongest. As illustrated in FIG. 3, apparatus 300 comprises polepieces 307P and 3070. As an example, polepiece 307P may be the piece of magnetic material near the north pole of magnetic lens 307M, and polepiece 3070 may be the piece of magnetic material near the south pole of magnetic lens 307M. When the current in magnetic lens coil 307C changes directions, then the polarity of the magnetic poles may also change. In the context of this disclosure, the positioning of electron detectors (e.g., signal electron detector 312 of FIG. 3), beam deflectors (e.g., beam deflectors 308-311 of FIG. 3), electrodes (e.g., control electrode 314 of FIG. 3) may be described with reference to the position of polepiece 307P located closest to the point where primary optical axis 300-1 intersects sample 315. Polepiece 307P of magnetic lens 307M may comprise a magnetic pole made of a soft magnetic material, such as electromagnetic iron, which concentrates the magnetic field substantially within the cavity of magnetic lens 307M. Polepieces 307P and 3070 may be high-resolution polepieces, multiuse polepieces, or high-contrast polepieces, for example.

As illustrated in FIG. 3, polepiece 307P may comprise an opening 307R configured to allow primary electron beam 300B1 to pass through and allow signal electrons to reach signal detectors 306 and 312. Opening 307R of polepiece 307P may be circular, substantially circular, or non-circular in cross-section. In some embodiments, the geometric center of opening 307R of polepiece 307P may be aligned with primary optical axis 300-1. In some embodiments, as illustrated in FIG. 3, polepiece 307P may be the furthest downstream horizontal section of magnetic lens 307M and may be substantially parallel to a plane of sample 315. Polepieces (e.g., 307P and 307O) are one of several distinguishing features of magnetic lens over electrostatic lens. Because polepieces are magnetic components adjacent to the magnetic poles of a magnetic lens, and because electrostatic lenses do not produce a magnetic field, electrostatic lenses do not have polepieces.

One of several ways to separately detect signal electrons such as SEs and BSEs based on their emission energy includes passing the signal electrons generated from probe spots on sample 315 through an energy filtering device. In some embodiments, control electrode 314 may be configured to function as an energy filtering device and may be disposed between sample 315 and signal electron detector 312. In some embodiments, control electrode 314 may be disposed between sample 315 and magnetic lens 307M along the primary optical axis 300-1. Control electrode 314 may be biased with reference to sample 315 to form a potential barrier for the signal electrons having a threshold emission energy. For example, control electrode 314 may be biased negatively with reference to sample 315 such that a portion of the negatively charged signal electrons having energies below the threshold emission energy may be deflected back to sample 315. As a result, only signal electrons that have emission energies higher than the energy barrier formed by control electrode 314 propagate towards signal electron detector 312. It is appreciated that control electrode 314 may perform other functions as well, for example, affecting the angular distribution of detected signal electrons on signal electron detectors 306 and 312 based on a voltage applied to control electrode. In some embodiments, control electrode 314 may be electrically connected via a connector (not illustrated) with the controller (not illustrated), which may be configured to apply a voltage to control electrode 314. The controller may also be configured to apply, maintain, or adjust the applied voltage. In some embodiments, control electrode 314 may comprise one or more pairs of electrodes configured to provide more flexibility of signal control to, for example, adjust the trajectories of signal electrons emitted from sample 315.

In some embodiments, sample 315 may be disposed on a plane substantially perpendicular to primary optical axis 300-1. The position of the plane of sample 315 may be adjusted along primary optical axis 300-1 such that a distance between sample 315 and signal electron detector 312 may be adjusted. In some embodiments, sample 315 may be electrically connected via a connector with controller (not illustrated), which may be configured to supply a voltage to sample 315. The controller may also be configured to maintain or adjust the supplied voltage.

In currently existing SEMs, signals generated by detection of secondary electrons and backscattered electrons are used in combination for imaging surfaces, detecting and analyzing defects, obtaining topographical information, morphological and compositional analysis, among others. By detecting the secondary electrons and backscattered electrons, the top few layers and the layers underneath may be imaged simultaneously, thus potentially capturing underlying defects, such as buried particles, overlay errors, among others. However, overall image quality may be affected by the efficiency of detection of secondary electrons as well as backscattered electrons. While high-efficiency secondary electron detection may provide high-quality images of the surface, the overall image quality may be inadequate because of inferior backscattered electron detection efficiency. Therefore, it may be beneficial to improve backscattered electron detection efficiency to obtain high-quality imaging, while maintaining high throughput.

As illustrated in FIG. 3, apparatus 300 may comprise signal electron detector 312 located immediately upstream of polepiece 307P and within the cavity of magnetic lens 307M. Signal electron detector 312 may be placed between primary electron beam deflector 311 and polepiece 307P. In some embodiments, signal electron detector 312 may be placed within the cavity of magnetic lens 307M such that there are no primary electron beam deflectors between signal electron detector 312 and sample 315.

In some embodiments, polepiece 307P may be electrically grounded or maintained at ground potential to minimize the influence of the retarding electrostatic field associated with sample 315 on signal electron detector 312, therefore minimizing the electrical damage, such as arcing, that may be caused to signal electron detector 312. In a configuration such as shown in FIG. 3, the distance between signal electron detector 312 and sample 315 may be reduced so that the BSE detection efficiency and the image quality may be enhanced while minimizing the occurrence of electrical failure or damage to signal electron detector 312.

In some embodiments, signal electron detectors 306 and 312 may be configured to detect signal electrons having a wide range of emission polar angles and emission energies. For example, because of the proximity of signal electron detector 312 to sample 315, it may be configured to collect backscattered electrons having a wide range of emission polar angles, and signal electron detector 306 may be configured to collect or detect secondary electrons having low emission energies.

Signal electron detector 312 may comprise an opening configured to allow passage of primary electron beam 300B1 and signal electron beam 300B4. In some embodiments, the opening of signal electron detector 312 may be aligned such that a central axis of the opening may substantially coincide with primary optical axis 300-1. The opening of signal electron detector 312 may be circular, rectangular, elliptical, or any other suitable shape. In some embodiments, the size of the opening of signal electron detector 312 may be chosen, as appropriate. For example, in some embodiments, the size of the opening of signal electron detector 312 may be smaller than the opening of polepiece 307P close to sample 315. In some embodiments, where the signal electron detector 306 is a single-channel detector, the opening of signal electron detector 312 and the opening of signal electron detector 306 may be aligned with each other and with primary optical axis 300-1. In some embodiments, signal electron detector 306 may comprise a plurality of electron detectors, or one or more electron detectors having a plurality of detection channels. In embodiments where the signal electron detector 306 comprises a plurality of electron detectors, one or more detectors may be located off-axis with respect to primary optical axis 300-1. In the context of this disclosure, “off-axis” may refer to the location of an element such as a detector, for example, such that the primary axis of the element forms a non-zero angle with the primary optical axis of the primary electron beam. In some embodiments, the signal electron detector 306 may further comprise an energy filter configured to allow a portion of incoming signal electrons having a threshold energy to pass through and be detected by the electron detector.

The location of signal electron detector 312 within the cavity of magnetic lens 307M as shown in FIG. 3 may further enable easier assembly and alignment of signal electron detector 312 with other electron-optical components of apparatus 300. Electrically grounded polepiece 307P may substantially shield signal electron detector 312 from the influence of the retarding electrostatic field of electrostatic lens 307ES formed by polepiece 307P, control electrode 314, and sample 315.

One of several ways to enhance image quality and signal-to-noise ratio may include detecting more backscattered electrons emitted from the sample. The angular distribution of emission of backscattered electrons may be represented by a cosine dependence of the emission polar angle (cos(θ), where θ is the emission polar angle between the backscattered electron beam and the primary optical axis). While a signal electron detector may efficiently detect backscattered electrons of medium emission polar angles, the large emission polar angle backscattered electrons may remain undetected or inadequately detected to contribute towards the overall imaging quality. Therefore, it may be desirable to add another signal electron detector to capture large angle backscattered electrons.

While not specifically depicted, it should be understood that features and embodiments described herein can also be applied to multi-beam SEM as well.

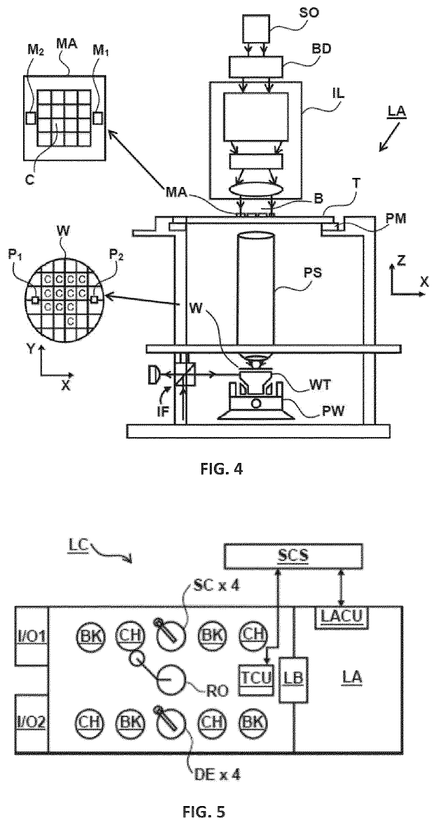

As a further brief introduction, FIG. 4 schematically depicts a lithographic apparatus LA. The lithographic apparatus LA includes an illumination system (also referred to as illuminator) IL configured to condition a radiation beam B (e.g., UV radiation, DUV radiation or EUV radiation), a mask support (e.g., a mask table) T constructed to support a patterning device (e.g., a mask) MA and connected to a first positioner PM configured to accurately position the patterning device MA in accordance with certain parameters, a substrate support (e.g., a wafer table) WT configured to hold a substrate (e.g., a resist coated wafer) W and coupled to a second positioner PW configured to accurately position the substrate support in accordance with certain parameters, and a projection system (e.g., a refractive projection lens system) PS configured to project a pattern imparted to the radiation beam B by patterning device MA onto a target portion C (e.g., comprising one or more dies) of the substrate W.

In operation, the illumination system IL receives a radiation beam from a radiation source SO, e.g., via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus LA may be of a type wherein at least a portion of the substrate may be covered by a liquid having a relatively high refractive index, e.g., water, so as to fill a space between the projection system PS and the substrate W—which is also referred to as immersion lithography. More information on immersion techniques is given in U.S. Pat. No. 6,952,253, which is incorporated herein by reference.

The lithographic apparatus LA may also be of a type having two or more substrate supports WT (also named “dual stage”). In such “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus LA may comprise a measurement stage. The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g., mask, MA which is held on the mask support MT, and is patterned by the pattern (design layout) present on patterning device MA. Having traversed the mask MA, the radiation beam B passes through the projection system PS, which focuses the beam onto a target portion C of the substrate W. With the aid of the second positioner PW and a position measurement system IF, the substrate support WT can be moved accurately, e.g., so as to position different target portions C in the path of the radiation beam B at a focused and aligned position. Similarly, the first positioner PM and possibly another position sensor (which is not explicitly depicted in FIG. 4) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

FIG. 5 depicts a schematic overview of a lithographic cell LC. As shown in FIG. 5 the lithographic apparatus LA may form part of lithographic cell LC, also sometimes referred to as a lithocell or (litho)cluster, which often also includes apparatus to perform pre- and post-exposure processes on a substrate W. Conventionally, these include spin coaters SC configured to deposit resist layers, developers DE to develop exposed resist, chill plates CH and bake plates BK, e.g. for conditioning the temperature of substrates, W e.g., for conditioning solvents in the resist layers. A substrate handler, or robot, RO picks up substrates W from input/output ports I/O1, I/O2, moves them between the different process apparatus and delivers the substrates W to the loading bay LB of the lithographic apparatus LA. The devices in the lithocell, which are often also collectively referred to as the track, are typically under the control of a track control unit TCU that in itself may be controlled by a supervisory control system SCS, which may also control the lithographic apparatus LA, e.g., via lithography control unit LACU.

In order for the substrates W (FIG. 4) exposed by the lithographic apparatus LA to be exposed correctly and consistently, it is desirable to inspect substrates to measure properties of patterned structures, such as overlay errors between subsequent layers, line thicknesses, critical dimensions (CD), etc. For this purpose, inspection tools (not shown) may be included in the lithocell LC. If errors are detected, adjustments, for example, may be made to exposures of subsequent substrates or to other processing steps that are to be performed on the substrates W, especially if the inspection is done before other substrates W of the same batch or lot are still to be exposed or processed.

An inspection apparatus, which may also be referred to as a metrology apparatus, is used to determine properties of the substrates W (FIG. 4), and, in particular, how properties of different substrates W vary or how properties associated with different layers of the same substrate W vary from layer to layer. The inspection apparatus may alternatively be constructed to identify defects on the substrate W and may, for example, be part of the lithocell LC, or may be integrated into the lithographic apparatus LA, or may even be a stand-alone device. The inspection apparatus may measure the properties on a latent image (image in a resist layer after the exposure), or on a semi-latent image (image in a resist layer after a post-exposure bake step PEB), or on a developed resist image (in which the exposed or unexposed parts of the resist have been removed), or even on an etched image (after a pattern transfer step such as etching).

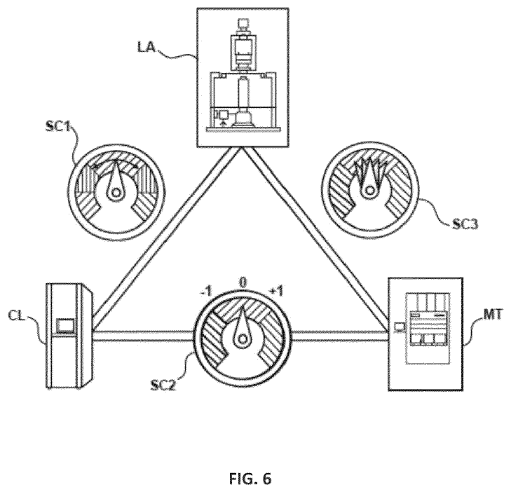

FIG. 6 depicts a schematic representation of holistic lithography, representing a cooperation between three technologies to optimize semiconductor manufacturing. Typically, the patterning process in a lithographic apparatus LA is one of the most critical steps in the processing which requires high accuracy of dimensioning and placement of structures on the substrate W (FIG. 4). To ensure this high accuracy, three systems (in this example) may be combined in a so called “holistic” control environment as schematically depicted in FIG. 6. One of these systems is the lithographic apparatus LA which is (virtually) connected to a metrology apparatus (e.g., a metrology tool) MT (a second system), and to a computer system CL (a third system). A “holistic” environment may be configured to optimize the cooperation between these three systems to enhance the overall process window and provide tight control loops to ensure that the patterning performed by the lithographic apparatus LA stays within a process window. The process window defines a range of process parameters (e.g., dose, focus, overlay) within which a specific manufacturing process yields a defined result (e.g., a functional semiconductor device)—typically within which the process parameters in the lithographic process or patterning process are allowed to vary.

The computer system CL may use (part of) the design layout to be patterned to predict which resolution enhancement techniques to use and to perform computational lithography simulations and calculations to determine which mask layout and lithographic apparatus settings achieve the largest overall process window of the patterning process (depicted in FIG. 6 by the double arrow in the first scale SC1). Typically, the resolution enhancement techniques are arranged to match the patterning possibilities of the lithographic apparatus LA. The computer system CL may also be used to detect where within the process window the lithographic apparatus LA is currently operating (e.g., using input from the metrology tool MT) to predict whether defects may be present due to, for example, sub-optimal processing (depicted in FIG. 6 by the arrow pointing “0” in the second scale SC2).

The metrology apparatus (tool) MT may provide input to the computer system CL to enable accurate simulations and predictions and may provide feedback to the lithographic apparatus LA to identify possible drifts, e.g., in a calibration status of the lithographic apparatus LA (depicted in FIG. 6 by the multiple arrows in the third scale SC3).

In lithographic processes, it is desirable to make frequent measurements of the structures created, e.g., for process control and verification. Different types of metrology tools MT for making such measurements are known, including scanning electron microscopes or various forms of optical metrology tool, image based or scatterometery-based metrology tools. Scatterometers are versatile instruments which allow measurements of the parameters of a lithographic process by having a sensor in the pupil or a conjugate plane with the pupil of the objective of the scatterometer, measurements usually referred as pupil-based measurements, or by having the sensor in the image plane or a plane conjugate with the image plane, in which case the measurements are usually referred as image or field-based measurements. Such scatterometers and the associated measurement techniques are further described in patent applications US20100328655, US2011102753A1, US20120044470A, US20110249244, US20110026032 or EP1,628,164A, incorporated herein by reference in their entirety. Aforementioned scatterometers may measure features of a substrate such as gratings using light from soft x-ray and visible to near-IR wavelength range, for example.

In some embodiments, a scatterometer MT is an angular resolved scatterometer. In these embodiments, scatterometer reconstruction methods may be applied to the measured signal to reconstruct or calculate properties of a grating and/or other features in a substrate. Such reconstruction may, for example, result from simulating interaction of scattered radiation with a mathematical model of the target structure and comparing the simulation results with those of a measurement. Parameters of the mathematical model are adjusted until the simulated interaction produces a diffraction pattern similar to that observed from the real target.

In some embodiments, scatterometer MT is a spectroscopic scatterometer MT. In these embodiments, spectroscopic scatterometer MT may be configured such that the radiation emitted by a radiation source is directed onto target features of a substrate and the reflected or scattered radiation from the target is directed to a spectrometer detector, which measures a spectrum (i.e., a measurement of intensity as a function of wavelength) of the specular reflected radiation. From this data, the structure or profile of the target giving rise to the detected spectrum may be reconstructed, e.g., by Rigorous Coupled Wave Analysis and non-linear regression or by comparison with a library of simulated spectra.

In some embodiments, scatterometer MT is an ellipsometric scatterometer. The ellipsometric scatterometer allows for determining parameters of a lithographic process by measuring scattered radiation for each polarization states. Such a metrology apparatus (MT) emits polarized light (such as linear, circular, or elliptic) by using, for example, appropriate polarization filters in the illumination section of the metrology apparatus. A source suitable for the metrology apparatus may provide polarized radiation as well. Various embodiments of existing ellipsometric scatterometers are described in U.S. patent application Ser. Nos. 11/451,599, 11/708,678, 12/256,780, 12/486,449, 12/920,968, 12/922,587, 13/000,229, 13/033,135, 13/533,110 and 13/891,410 incorporated herein by reference in their entirety.

In some embodiments, scatterometer MT is adapted to measure the overlay of two misaligned gratings or periodic structures (and/or other target features of a substrate) by measuring asymmetry in the reflected spectrum and/or the detection configuration, the asymmetry being related to the extent of the overlay. The two (typically overlapping) grating structures may be applied in two different layers (not necessarily consecutive layers) and may be formed substantially at the same position on the wafer. The scatterometer may have a symmetrical detection configuration as described e.g., in patent application EP1,628,164A, such that any asymmetry is clearly distinguishable. This provides a way to measure misalignment in gratings. Further examples for measuring overlay may be found in PCT patent application publication no. WO 2011/012624 or US patent application US 20160161863, incorporated herein by reference in their entirety.

Focus and dose used in lithography process may be determined by scatterometry (or alternatively by scanning electron microscopy) as described in US patent application US2011-0249244, incorporated herein by reference in its entirety. A single structure (e.g., feature in a substrate) may be used which has a unique combination of critical dimension and sidewall angle measurements for each point in a focus energy matrix (FEM—also referred to as Focus Exposure Matrix). If these unique combinations of critical dimension and sidewall angle are available, the focus and dose values may be uniquely determined from these measurements.

A metrology target may be an ensemble of composite gratings and/or other features in a substrate, formed by a lithographic process, commonly in resist, but also after etch processes, for example. Typically, the pitch and line-width of the structures in the gratings depend on the measurement optics (in particular the NA of the optics) to be able to capture diffraction orders coming from the metrology targets. A diffracted signal may be used to determine shifts between two layers (also referred to “overlay”) or may be used to reconstruct at least part of the original grating as produced by the lithographic process. This reconstruction may be used to provide guidance of the quality of the lithographic process and may be used to control at least part of the lithographic process. Targets may have smaller sub-segmentation which are configured to mimic dimensions of the functional part of the design layout in a target. Due to this sub-segmentation, the targets will behave more similarly to the functional part of the design layout such that the overall process parameter measurements resemble the functional part of the design layout. The targets may be measured in an underfilled mode or in an overfilled mode. In the underfilled mode, the measurement beam generates a spot that is smaller than the overall target. In the overfilled mode, the measurement beam generates a spot that is larger than the overall target. In such overfilled mode, it may also be possible to measure different targets simultaneously, thus determining different processing parameters at the same time.

Overall measurement quality of a lithographic parameter using a specific target is at least partially determined by the measurement recipe used to measure this lithographic parameter. The term “substrate measurement recipe” may include one or more parameters of the measurement itself, one or more parameters of the one or more patterns measured, or both. For example, if the measurement used in a substrate measurement recipe is a diffraction-based optical measurement, one or more of the parameters of the measurement may include the wavelength of the radiation, the polarization of the radiation, the incident angle of radiation relative to the substrate, the orientation of radiation relative to a pattern on the substrate, etc. One of the criteria to select a measurement recipe may, for example, be a sensitivity of one of the measurement parameters to processing variations. More examples are described in US patent application US2016-0161863 and published US patent application US 2016/0370717A1 incorporated herein by reference in its entirety.

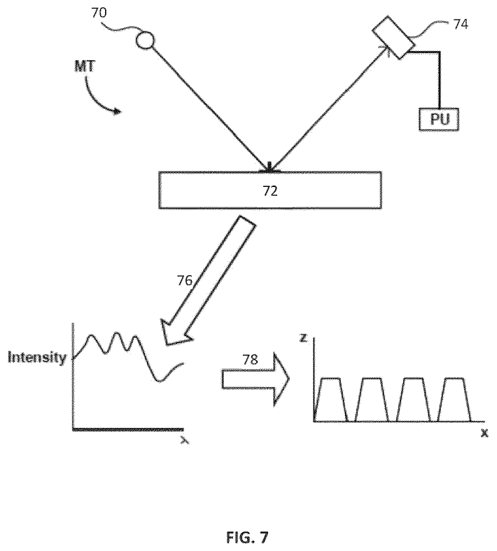

FIG. 7 illustrates an example metrology apparatus (tool) MT, such as a scatterometer. MT comprises a broadband (white light) radiation projector 70 which projects radiation onto a substrate 72. The reflected or scattered radiation is passed to a spectrometer detector 74, which measures a spectrum 76 (i.e., a measurement of intensity as a function of wavelength) of the specular reflected radiation. From this data, the structure or profile giving rise to the detected spectrum may be reconstructed 78 by processing unit PU, e.g., by Rigorous Coupled Wave Analysis and non-linear regression or by comparison with a library of simulated spectra as shown at the bottom of FIG. 7. In general, for the reconstruction, the general form of the structure is known and some parameters are assumed from knowledge of the process by which the structure was made, leaving only a few parameters of the structure to be determined from the scatterometry data. Such a scatterometer may be configured as a normal-incidence scatterometer or an oblique-incidence scatterometer, for example.

It is often desirable to be able computationally determine how a patterning process would produce a desired pattern on a substrate. Computational determination may comprise simulation and/or modeling, for example. Models and/or simulations may be provided for one or more parts of the manufacturing process. For example, it is desirable to be able to simulate the lithography process of transferring the patterning device pattern onto a resist layer of a substrate as well as the yielded pattern in that resist layer after development of the resist, simulate metrology operations such as the determination of overlay, and/or perform other simulations. The objective of a simulation may be to accurately predict, for example, metrology metrics (e.g., overlay, a critical dimension, a reconstruction of a three dimensional profile of features of a substrate, a dose or focus of a lithography apparatus at a moment when the features of the substrate were printed with the lithography apparatus, etc.), manufacturing process parameters (e.g., edge placements, aerial image intensity slopes, sub resolution assist features (SRAF), etc.), and/or other information which can then be used to determine whether an intended or target design has been achieved. The intended design is generally defined as a pre-optical proximity correction design layout which can be provided in a standardized digital file format such as GDSII, OASIS or another file format.

Simulation and/or modeling can be used to determine one or more metrology metrics (e.g., performing overlay and/or other metrology measurements), configure one or more features of the patterning device pattern (e.g., performing optical proximity correction), configure one or more features of the illumination (e.g., changing one or more characteristics of a spatial/angular intensity distribution of the illumination, such as change a shape), configure one or more features of the projection optics (e.g., numerical aperture, etc.), and/or for other purposes. Such determination and/or configuration can be generally referred to as mask optimization, source optimization, and/or projection optimization, for example. Such optimizations can be performed on their own, or combined in different combinations. One such example is source-mask optimization (SMO), which involves the configuring of one or more features of the patterning device pattern together with one or more features of the illumination. The optimizations may use the parameterized model described herein to predict values of various parameters (including images, etc.), for example.

In some embodiments, an optimization process of a system may be represented as a cost function. The optimization process may comprise finding a set of parameters (design variables, process variables, etc.) of the system that minimizes the cost function. The cost function can have any suitable form depending on the goal of the optimization. For example, the cost function can be weighted root mean square (RMS) of deviations of certain characteristics (evaluation points) of the system with respect to the intended values (e.g., ideal values) of these characteristics. The cost function can also be the maximum of these deviations (i.e., worst deviation). The term “evaluation points” should be interpreted broadly to include any characteristics of the system or fabrication method. The design and/or process variables of the system can be confined to finite ranges and/or be interdependent due to practicalities of implementations of the system and/or method. In the case of a lithographic projection apparatus, the constraints are often associated with physical properties and characteristics of the hardware such as tunable ranges, and/or patterning device manufacturability design rules. The evaluation points can include physical points on a resist image on a substrate, as well as non-physical characteristics such as dose and focus, for example.

During fabrication of semiconductor devices, various material and feature parameters are monitored and/or adjusted. Feature parameters can include overlay, sidewall angle, critical dimension, overlay, overlay uniformity, etc. Material parameters can include growth rate, composition, ion implantation dose, thickness, etc. As feature parameters can depend on material parameters and as material parameters can be influenced by feature parameters, “feature parameters” is used herein to refer to a metric which is measured before, during, or after fabrication and which therefore can be assumed to be related to at least one fabrication step and/or device performance. Fabrication can involve one or more delicate steps, and fabrication control relies on metrology or measurement of various material and feature parameters to control and/or improve the fabrication process. Fabrication control can include one or more process control methods, such as lean six sigma, to monitor processes, detect errors and variations, and adjust fabrication parameters to maximize semiconductor device performance and minimize cost.

Some feature parameters can be measured by more than one measurement or metrology process. For example, overlay—which is a measure of layer-to-layer shift between at least two fabrication layers—can be measured by optical metrology and by SEM metrology. Each metrology can have benefits and drawbacks, as (1) metrology time can be costly and vary between techniques, (2) precision and accuracy of techniques can vary, and (3) some metrology techniques can be deleterious and/or destructive. For example, SEM metrology is the gold standard for measurement of certain feature parameters-including overlay (OVL), critical dimension (CD), and critical dimension uniformity (CD(U)) at both the global (i.e., wafer level) and local (i.e., a portion of a wafer, such as chip level) scale. However, SEM metrology is time consuming, as features are measured individually, and deleterious, as high energy electrons can burn one or more materials of the semiconductor device. SEM metrology is therefore not the process of record for determining OVL, CD, and/or CD(U)). Instead, optical metrology is typically the process of record for determining OVL, CD, and CD(U) during high-volume manufacturing.

Optical metrology can determine OVL, CD, and CD(U) in at least two ways. In a first case, multiple wavelengths of light at pre-selected polarizations can be reflected off of specially designed structures (e.g., diffraction gratings) at multiple sampling points on the wafer such that their reflections can be captured and measured as a function of location, intensity, polarization, phase, etc. A deterministic formula can be used to determine a measure of overlay based on a slope of asymmetric intensity between the emitted and reflected light over the multiple wavelengths. In this manner, at each sampling point OVL can be determined as a function of the multiple wavelengths and polarizations. CD and CD(U) can be determined based on OVL and knowledge of the structure of the layers and/or the device structure.

In a second case, scattering intensity can be determined at a single wavelength for a sampling point using rigorous coupled wave analysis (RCWA). The single wavelength can be chosen based on the structure and/or material characteristics of the semiconductor device. The single wavelength can be chosen experimentally and/or based on simulation from a set of multiple wavelengths and/or polarizations. The measured intensity of the reflected light is decomposed into electric and magnetic components (i.e., TM and TE modes) through interferometry. OVL and CD are determined based on the electric and magnetic components using a truncated Fourier-space expansion and Maxwell's equations. The truncated Fourier series are placed into Maxwell's equations for a model (with floating model parameters) of the structure of the sampling point. The model parameters, such as OVL and CD, are solved for using eigenmode expansion and truncation. The resulting Fourier coefficients are compared to those expected for the given OVL and CD and if they agree (to within a tolerance or threshold), the OVL and CD are output. Otherwise, the floating model parameters are adjusted and the model is solved in another iteration. Truncation of the Fourier series in RCWA can be a source of inaccuracy.

In both cases, optical metrology outputs a global measurement because optical signals are averages over the measurement area of the sampling points. This can cause additional inaccuracy in CD(U) measurements, but also smoothing of OVL and CD measurements. Optical metrology can be significantly faster than SEM metrology, which is why it is the process of record, but accuracy is lost when compared to SEM metrology which is the gold standard. However, the accuracy of measurements based on optical metrology data can be improved by also referring to SEM data.

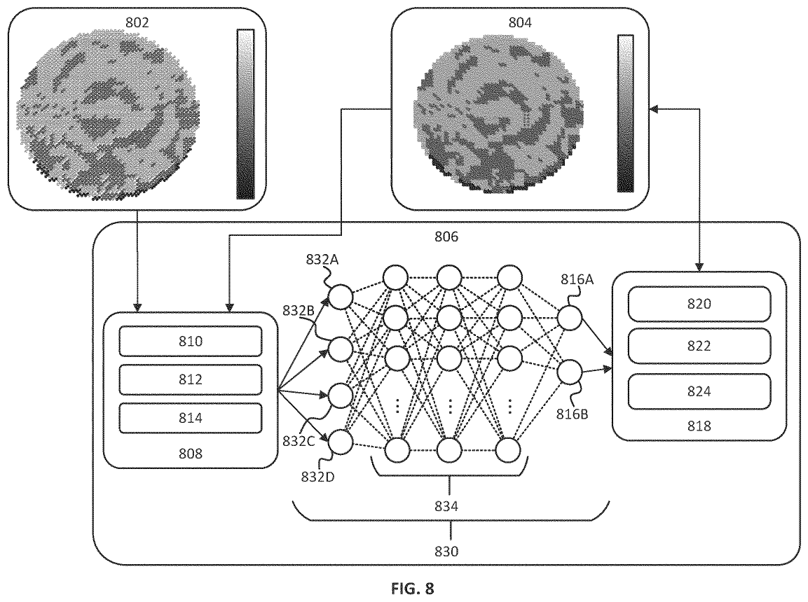

FIG. 8 illustrates a summary of operations of a present method for training a model to generate pseudo-scanning electron microscopy (SEM) metrology data based on optical metrology data, according to some embodiments. Optical data 802 is collected by one or more optical metrology tools. Optical data 802 can be obtained in any appropriate method and by any appropriate apparatus, such as the apparatus of FIG. 4 based on the structures of FIGS. 5 and 7 and as further explained in reference to FIG. 6. The optical data 802 corresponds to a specific step in the wafer fabrication process. The specific step can be any of the fabrication steps (e.g., lithography, etch, deposition, fill, clean, etc.) for which SEM metrology data or pseudo-SEM metrology data is useful and for which optical metrology data can be acquired. The specific step is usually a completed step, where metrology is performed after the step is completed, but can instead by a mid-process step or one or more substeps. For example, the specific step can be an etch step, where the optical data 802 is obtained after one or more diffraction grating is created by etching. In another example, the specific step can be a lithography step and more specifically be a photoresist hardening step or substep where the optical data 802 is obtained after the photoresist is applied, exposed, developed and/or hardened. The specific step can be selected based on process control needs or other desires by an operator. For example, the specific step can be selected based on inadequacy of optical metrology data. If one or more of the optical data 802 is not accurate or precise enough to effectuate process control, the specific step can be selected for model generation and application. By using the trained model to generate pseudo-SEM metrology data, the specific step can be better evaluated, monitored, and/or controlled. The optical data 802 can comprise optical data for a portion or all of a wafer. The optical data can comprise scatterometry data, including multiple wavelengths and/or polarizations as used to calculate OVL as previously described, and/or single wavelength intensity as used in RCWA as previously described. The optical data can comprise measurements corresponding to one or more sampling points, where sampling points can be distributed (evenly or unevenly) across the wafer surface. The optical data 802 is represented by a depiction of OVL magnitude as measured via optical metrology for each sampling point of an example wafer. The optical data 802 can be multi-dimensional. For example, in multi-wavelength optical metrology, multiple intensities and phases are determined at multiple wavelengths and polarizations for a sampling point. Each of these values can be includes in the optical data 802, such that each sampling point corresponds to an array of data. Additionally, the optical data 802 can include one or more optical-metrology-derived performance indicators and/or other metrics calculated from the optical data 802. For example, the optical data 802 can include both wavelength and intensity information and an OVL determined from the optical data 802 for sampling point.

SEM data 804 is collected by one or more SEM metrology tools. SEM data 804 can be obtained in any appropriate method and by any appropriate apparatus, such as the apparatus of FIGS. 1-3. The SEM data 804 corresponds to the same specific step in the wafer fabrication process as the optical data 802. The SEM data 804 and the optical data can be obtained from sequential metrology steps without intervening wafer processing. The SEM data 804 can comprise SEM data for a portion up to substantially all of the wafer. The SEM data 804 can be taken and/or acquired for points distributed across the wafer surface. The SEM data 804 acquisition points can correspond to the optical data sampling points or, alternatively, one or more of the SEM acquisition points may not correspond to any of the optical data sampling points. The SEM acquisition points can be the optical data sampling points, in which case the SEM data 804 can include measurement of one or more diffraction gratings or structures adjacent to one or more diffraction gratings. The SEM acquisition points can be near the optical data sampling points, such as at vias near the diffraction gratings. The SEM acquisition points can also be in different areas than the optical data sampling points. The SEM data 804 is represented by a depiction of OVL magnitude as measured via optical metrology for each acquisition point of an example wafer. The SEM data 804 can comprise SEM images for each acquisition point. The SEM data 804 can optionally comprise SEM-derived performance indicators and/or other metrics calculated from the SEM images for each acquisition point. For example, the SEM data 804 can include both an SEM image and an OVL determined from the SEM image for an acquisition point. The SEM data 804 can be multi-dimensional, where dimensionality is determined by the number of performance indicators and/or metric included in the SEM data 804. The performance indicators and/or metrics can be determined from the SEM images by an operator or user, or by one or more software programs, controllers, and/or models.

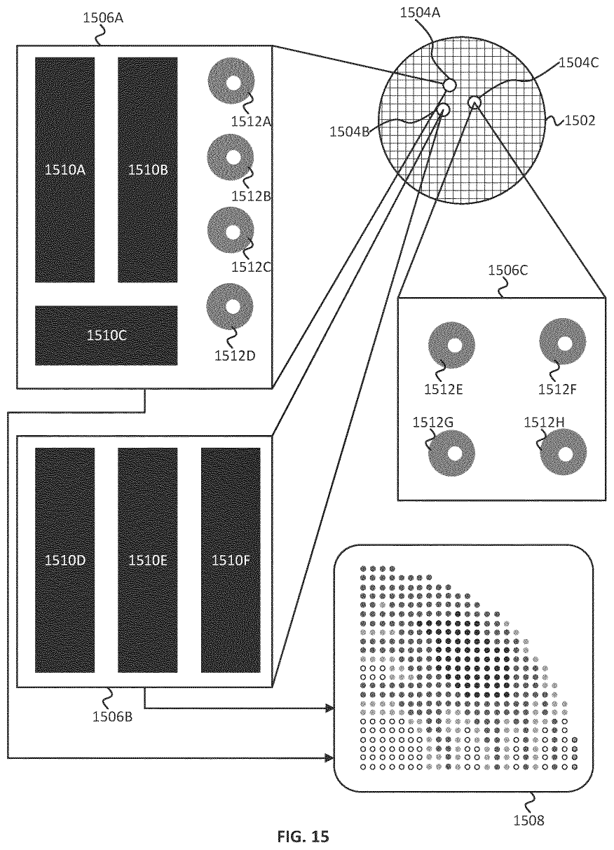

The optical data 802 and the SEM data 804 are combined to generate a training data set 808. The training data set 808 can also include one or more optical-metrology-derived performance indicators 810, one or more SEM-derived performance indicators 812, and one or more feature parameters 814. The training data set 808 can comprise one or more element corresponding to input components and one or more elements corresponding to output components. The input components of training data set 808 can comprise the optical data 802 and/or one or more optical-metrology-derived performance indicators 810 (where some optical-metrology-derived performance indicators can be determined as the optical data 802 is acquired and other optical-metrology-derived performance indicators can be determined as the training data set 808 is assembled). One or more feature values can be calculated for a feature based on the optical data 802 and the one or more optical-metrology-derived performance indicators 810. The feature values can be assembled into a feature vector. The output components of the training data set 808 can comprise the SEM data 804, one or more SEM-derived performance indicators 812, and/or one or more feature parameters 814. The one or more SEM-derived performance indicators 812 optionally include the one or more feature parameters 814 or the one or more feature parameter 814 can be calculated based on the SEM data 804 and/or the one or more SEM-derived performance indicators 812. The feature vectors of the training data, derived from the optical data 802 and the optical-metrology-derived performance indicators at sampling points in first areas, are labeled with based on the SEM data 804, one or more SEM-derived performance indicators 812, and/or one or more feature parameters 814 for at least one acquisition point in a second area. The first areas and the second areas will be further discussed later in connection with FIG. 15. The first area and the second area can be overlapping, partially overlapping, or non-overlapping. Alternatively, a correlation between the optical data 802 and/or the optical-metrology-derived performance indicators at sampling points in first areas and the SEM data 804, one or more SEM-derived performance indicators 812, and/or one or more feature parameters 814 are determined.

Based on the training data, a model trainer 806 trains a model 830 to generate an output 818 comprising one or more feature parameters 820 based on an input comprising optical data 802 and/or optical-metrology-derived performance indicators 810. The output 818 can further comprise a pseudo-SEM OVL 822, a pseudo-SEM CD(U) 824, etc. Alternatively, the feature parameters 820 can include the pseudo-SEM OVL 822, the pseudo-SEM CD(U) 824, etc. The output 818 can approximate SEM quality metrics and can include parameters not measured by optical metrology, including local CD(U). Hereinafter, “pseudo-SEM” is used to refer to a feature parameter, performance indicator, or other metric which is generated by the model based on optical data and which approximates or imitates an SEM-derived measurement or metric. “SEM-quality” can be used interchangeably with “pseudo-SEM” as a description. Pseudo-SEM data can have accuracy, resolution, confidence, uncertainty, and other data qualities values which are more like SEM data than like optical data. In some cases, the data qualities values for pseudo-SEM data can lie between the SEM data and the optical data quality values. In other cases the pseudo-SEM data quality values can be substantially the same as SEM data quality values.

The model 830 can be a machine learning model. The model 830 can comprise one or more inputs (832A-832D), one or more hidden layers 834, and one or more outputs 816A-816B. The model 830 can map the optical data 802 to the SEM-derived performance indicators 812. The machine learning model can be a neural network. The machine learning model can be a decision tree model. The machine learning network can be a random forest model. The machine learning model can be a random forest model. The machine learning model can be a support vector model. The machine learning model can be a k-nearest neighbor model. The machine learning model can also comprise one or more of the types or machine learning models or be an ensemble machine learning model. The machine leaning model can be a multivariate regression algorithm. The machine learning model can be an appropriate machine learning model and have any appropriate structure. Alternatively, the machine learning model can instead be a mathematical model. The mathematical model can be a regression model, including a linear regression model.

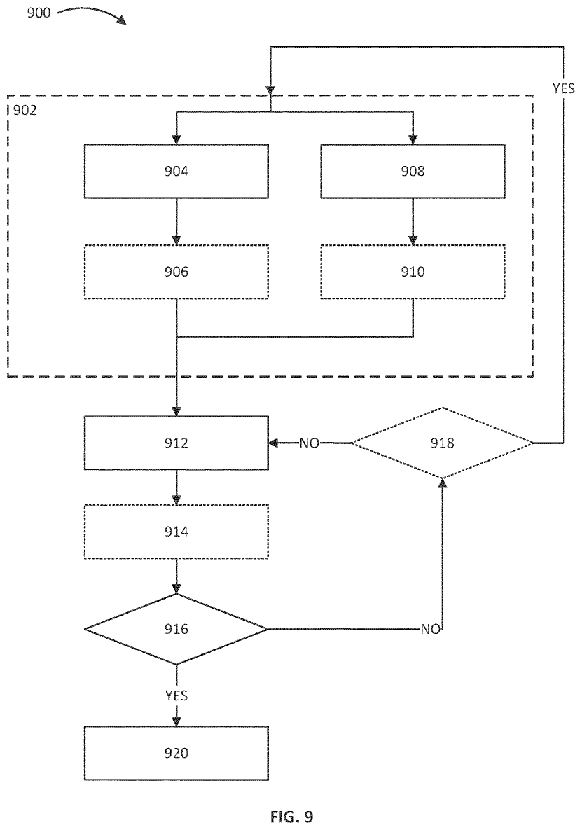

FIG. 9 illustrates an exemplary method 900 for training a model to generate pseudo-SEM metrology data based on optical metrology data, according to some embodiments. Each of these operations is described in detail below. The operations of method 900 presented below are intended to be illustrative. In some embodiments, method 900 may be accomplished with one or more additional operations not described, and/or without one or more of the operations discussed. Additionally, the order in which the operations of method 900 are illustrated in FIG. 9 and described below is not intended to be limiting. In some embodiments, one or more portions of method 900 may be implemented (e.g., by simulation, modeling, etc.) in one or more processing devices (e.g., one or more processors). The one or more processing devices may include one or more devices executing some or all of the operations of method 900 in response to instructions stored electronically on an electronic storage medium. The one or more processing devices may include one or more devices configured through hardware, firmware, and/or software to be specifically designed for execution of one or more of the operations of method 900, for example. For illustrative purposes, optional operations are depicted with dashed lines. However, operations which are shown with unbroken lines can also be optional or can be omitted.

At an operation 904, SEM data is obtained. The SEM data can correspond to acquisition points of one or more areas of one or more training wafers. The SEM data can be SEM images. The SEM data can be acquired from an SEM metrology device (i.e., a scanning electron microscope) or from one or more data storage devices or via one or more programs. The SEM data can be optionally filtered to reduce the number of SEM images in the dataset.

At an operation 906, one or more SEM-derived performance indicators are optionally determined. The SEM-derived performance indicator, which can be a feature parameter, can be one or more of overlay, overlay error, critical dimension, critical dimension uniformity, edge placement error, focus, dose, local overlay, local overlay error, local critical dimension, local critical dimension uniformity, one or more feature dimensions, etc. The SEM-derived performance indicators can be user selected. The SEM-derived performance indicators can include one or more SEM measurement parameters, where SEM measurement parameters can include at least one of one or more edge locations, one or more geometric image moments, one or more shape fitting dimensions, one or more shape fitting orientations, one or more contour shapes, one or more contour locations, one or more material compositions, etc. The SEM-derived performance indicator can include one or more SEM measurement parameters, a relationship between a feature of an SEM image and the one or more SEM measurement parameters, or a combination thereof. The lists of SEM-derived performance indicators above are illustrative only, as other performance indicators can be derived from SEM data.

At an operation 908, optical data is obtained. The optical data can correspond to sampling points of one or more areas of one or more training wafers, which can be the same training wafers for which the SEM data was obtained. The optical data can be pupil images. The optical data can be acquired from an optical metrology device (for example, a scatterometer) or from one or more data storage devices or via one or more programs. The optical data can be optionally filtered to reduce the amount of data in the dataset.

At an operation 910, one or more optical-metrology-derived performance indicators are optionally determined. The optical-metrology-derived performance indicator, which can be a feature parameter, can be one or more of total pupil average, inner pupil average, outer pupil average, total pupil variance, inner pupil variance, outer pupil variance, one or more lower-order Zernike coefficients, etc. The optical-metrology-derived performance indicators can be user selected. The optical-metrology-derived performance indicator can comprise optical metrology performance indicators obtained for different wavelengths, different polarizations, or different wavelengths and different polarizations. The optical-metrology-derived performance indicators can be determined based on one or more pupil images. The optical-metrology-derived performance indicators can be determined by a neural network.

At an operation 902, training data is generated. The operation 902 can include one or more of the operations 904-910. The training data can be generated based on the SEM data and/or the SEM-derived performance indicators and the optical data and/or the optical-metrology-derived performance indicators. The training data can comprise a set of inputs, corresponding to the optical data and/or the optical-metrology-derived performance indicators, and a set of outputs, corresponding to the SEM data and/or the SEM-derived performance indicators.

At an operation 912, a model (or other model, such as a mathematical model) is trained based on the training data. The training can be accomplished by any appropriate training method.

At an operation 914, the trained model is optionally tested based on test data. The test data, which can comprise input data and corresponding output data, can be operated upon by the trained model. The test data can be acquired from data storage or metrology devices. The test data can comprise optical metrology data, where SEM metrology data is acquired after or concurrently with the model operation. The test data can correspond to data from one or more areas on one or more wafers. The output of the trained model for the test data can then be compared to the known output of the test data, and a model accuracy determined.

At an operation 916, it is determined if a training criterion is satisfied. The training criterion can be a training goal or limit, such as a number of input and output pairs used to train the model, a training time limit, or can be a model accuracy or testing criterion. If the training criterion is satisfied, the trained model is output at an operation 920 for use to generate pseudo-SEM performance indicators based on optical metrology data. If the training criterion is not satisfied, flow continues to an operation 918. If the operation 918 is optionally omitted, flow can instead continue to either the operation 912, where the model is further trained on training data previously acquired, or to operation 902, to generate training data based on the operation 904 and 908. The direction of the flow will depend on the training criterion for the model. For example, if the training criterion is such that training is performed on the full set of training data at the operation 912, then flow will continue to the operation 902. In another example, if the training criterions is such that some training data of the training data set has not been used to train the model at the operation 912, then flow will continue to the operation 912, where previously unused training data is used to further train the model.

At the operation 918, it is optionally determined whether the current training data is exhausted. For example, it can be the case that the model has been trained on all extant training data but does not satisfy a test accuracy training criterion. If the current training data is exhausted, flow continues to the operations 902 to generate training data based on the operations 904 and 908. If the current training data is not exhausted, flow can continue to the operation 912, where the model is further trained on training data previously acquired and flow proceeds as previously described for the operation 912.

As described above, method 900 (and/or the other methods and systems described herein) is configured to provide a generic framework for training a model to generate pseudo-SEM metrology data based on optical metrology data.

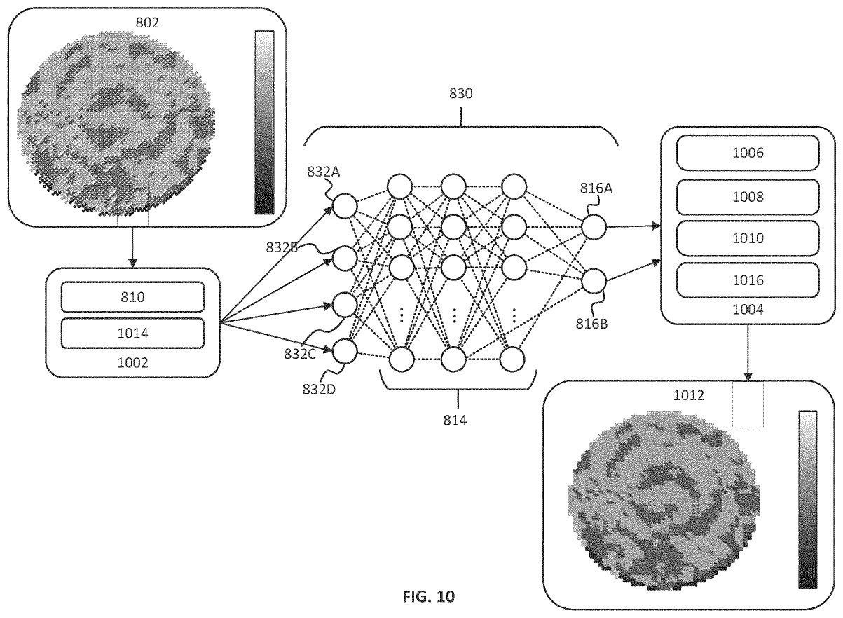

FIG. 10 illustrates a summary of operations of a present method for determining pseudo-SEM metrology data based on optical metrology data, according to some embodiments. A model 830 can operate on an optical-metrology-derived input 1002 to generate a pseudo-SEM output 1004. The optical-metrology-derived input 1002 can comprise the optical data 802, the one or more optical-metrology-derived performance indicators 810, and/or the one or more optical-metrology-derived feature parameters 1014. The optical data 802 is acquired by one or more optical metrology tools, as previously described. One or more optical-metrology-derived performance indicators 810 can be determined, along with one or more optical-metrology-derived feature parameters 1014, based on the optical data 802. The optical-metrology-derived input 1002 is then fed into the model 830. The model 830, as previously described, then outputs the pseudo-SEM output 1004, which can comprise one or more pseudo-SEM feature parameters 1010, pseudo-SEM OVL 1006, pseudo-SEM CD(U) 1008, etc. Optionally, the model 830 can output one or more pseudo-SEM measurement parameter 1016. The pseudo-SEM output 1004 can be used to optionally reconstruct or approximate one or more SEM measurement parameter, such as a reconstructed SEM OVL map of the wafer 1012.

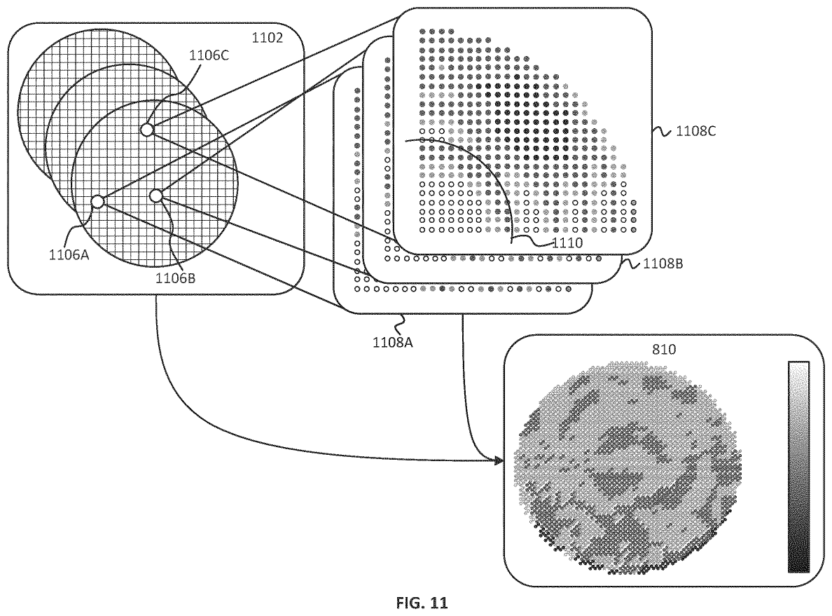

FIG. 11 illustrates a relationship between optical metrology data and optical-metrology-derived performance indicators, according to some embodiments. Optical metrology data 1102 is measured at specific sampling points over the surface of the wafer. The frequency and distribution of such sampling points depends on the wafer fabrication step and the device structure being fabricated. Each wafer can comprise multiple sampling points which can contain one or more optical measurement structures 1106A-1106C. For example, each sampling point can contain perpendicular sets of diffraction gratings which allow OVL to be measured in two orthogonal directions. The optical measurement structures 1106A-1106C can have dimensions on the order of optical wavelengths. For each of the optical measurement structures 1106A-1106C, a pupil image 1108A-1108C can be determined from the optical measurement structures 1106A-1106C. The pupil images 1108A-1108C can consist of measurements of scattering intensity at various angles of incidence for a diffracting-grating-based measurement structure. The pupil images 1108A-1108C can instead be matrices, arrays, or other multidimensional data structures. The pupil images 1108A-1108C can be reduced in dimensionality by computation of a global value for the optical measurement structures 1106A-1106C. For example, a pupil average can be determined from a pupil image, where each point in the pupil image corresponds to a value of intensity. The pupil average can be the average of all the intensity values included in the pupil image. An inner pupil average can be the average of all the intensity values in an inner ring of the pupil image. The inner ring is represented by the values inside of an arc 1110 because the pupil image is symmetric about the x and y axes and is therefore typically represented by a single quadrant of the pupil image. The inner ring is shown for explication only, and can have a larger or smaller radius which can depend on device structure. An outer pupil average can be the average of all the intensity values in the outer ring (i.e., outside the outer ring). Likewise, a total pupil variance, inner pupil variance, and outer pupil variance can be determined based on the pupil image and the intensity values it contains. Lower order Fourier coefficients and/or Zernike coefficients can be used instead of or together with a pupil image and/or one or more values derived from a pupil image. Zernike coefficients can be used together with Zernike polynomials to define variations in the pupil image. Fourier coefficients can be used to define the magnetic and electric components of reflected light.

The one or more optical-metrology-derived performance indicators 810 can be determined based on one or more of the optical metrology parameters described above in reference to the optical measurement structures 1106A-1106C and the pupil images 1108A-1108C. Optical metrology data 1102 can also comprise data not included in pupil measurements such as a measure of symmetry. For example, a measure of symmetry between a pair of wavelengths can be determined based on the intensity of light diffracted by a diffraction grating. The measure of symmetry can be a measure of asymmetric intensity, and can even be a measurement of distance-to-origin (DTO) in an asymmetric intensity plot or graph. One or more optical-metrology-derived performance indicators 810 could be determined based on DTO or another parameter derived from optical data, but not directly represented in a pupil image.

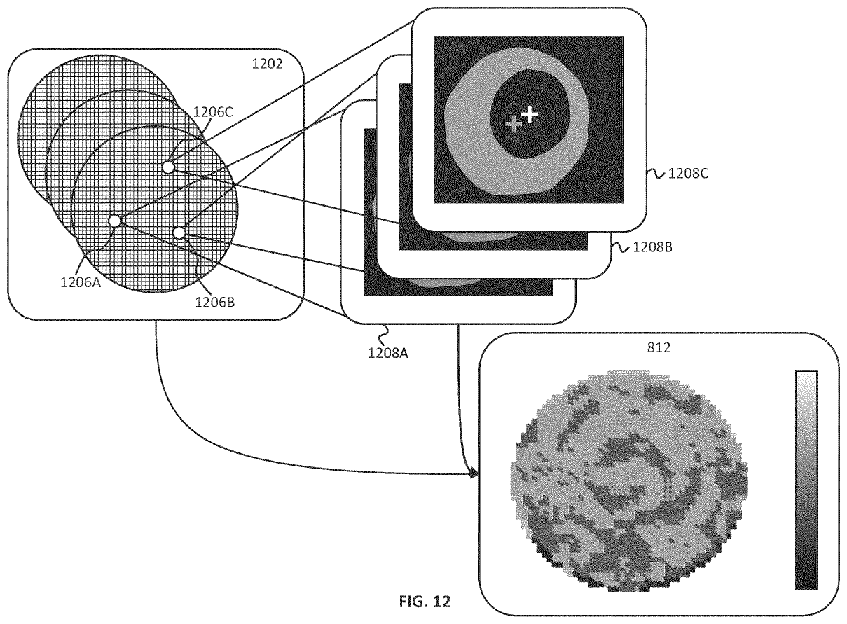

FIG. 12 illustrates a relationship between SEM metrology data and SEM-derived performance indicators, according to some embodiments. SEM metrology data 1202 is measured as acquisition points over the surface of the wafer. The SEM metrology data 1202 can comprise SEM images acquired at any point on the wafer, although some points are more valuable than other points. For instance, vias or other etched or filled features can be used to measure OVL, edge placement error (EPE), and other physical displacement metrics. SEM images of large features, such as metal contact pads, provide less information about the features and fabrication processes which have created the wafer. Metal contact pads can be large, such that they dominate an SEM image, and can be highly reflective or bright in SEM images, due to the electron-metal interactions. In some embodiments, particular structures are chosen for SEM imaging in order to generate SEM-derived performance indicators. For example, one or more via can be imaged, including vias at different locations (either in different chips/on different device or at different locations within the same device). For features, various parameters can be measured, such as center-of-gravity location, distance between center-of-gravities, feature size, via inner circle width, via inner circle height, via inner circle area, via outer circle width, via outer circle height, via outer circle area, etc. Each wafer can comprise multiple acquisition points which can contain one or more SEM measurement structures 1206A-1206C. For example, each acquisition point can a via with an inner and outer circle, as shown in SEM images 1208A-1208C. The one or more SEM measurement structures 1206A-1206C can have dimensions on the order of SEM resolution and/or approaching Moore's law limitations. For each of one or more SEM measurement structures 1206A-1206C, the SEM images 1208A-1208C can be acquired. From the SEM images 1208A-1208C one or more SEM measurement parameter can be determined. SEM measurement parameters can comprise one or more edge location, one or more geometric image moment, one or more shape fitting dimension, one or more shape fitting orientation, one or more contour shape, one or more contour location, one or more material composition, etc. From the SEM measurement parameters, or based on the SEM images 1208A-1208C themselves, one or more SEM-derived performance indicators 812 can be determined.

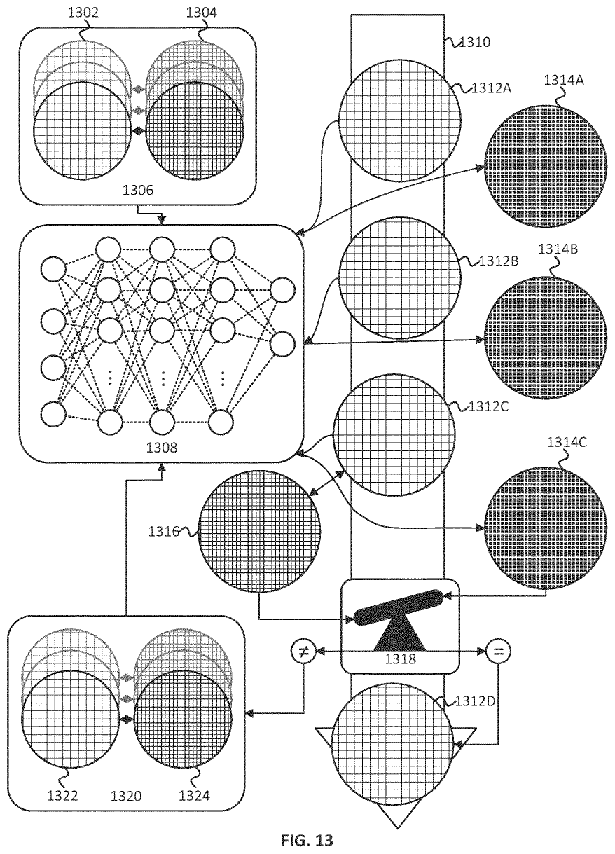

FIG. 13 illustrates a summary of operations of a present method for triggering retraining of the model, according to some embodiments. Optical metrology data 1302 and SEM metrology data 1304 is acquired for one or more training wafers and correlated to generate training data 1306. Based on the training data, the model 1308 is trained to generate parameters for features on a production wafer of the production wafers 1312A-1312D. The production wafers 1312A-1312D are a set of wafers produced by the process 1310 in high-volume manufacturing. The production wafers 1312A to 1312D are depicted as produced in order. Other wafers which are not depicted may also be produced. For example, the production wafer 1312A can correspond to a first batch of 25 wafers (where 25 wafers is a number of wafers provided as a non-limiting example only), and the production wafer 1312B can correspond to a second batch of 25 wafers. In some embodiments, all wafers may be optically imaged, but not all optical metrology data may be input into the model 1308. In other embodiments, all or substantially all wafers be optically images and all or substantially all optical metrology data may be input into the model 1308. For the production wafers 1312A to 1312D, optical metrology data is input into the model 1308 and pseudo-SEM performance indicators 1314A-1314C are output by the model 1308. The pseudo-SEM performance indicators 1314A-1314C can also be output to one or more process controller for monitoring, adjustment, and control of the process 1310 or previous processes.

The model 1308 is also periodically checked or compared to one or more production wafer to determine if the model is in agreement with the production wafers 1312C-1312D. The production wafer 1312C is selected for monitoring and SEM metrology data 1316 is acquired for the production wafer 1312C. The selection of the production wafer 1312C can be based on a periodic trigger. In a non-limiting example, monitoring can be performed every 50 wafers or once a day. The selection of the production wafer 1312C can also be triggered by one or more other performance indicator. In another non-limiting example, the selection of the production wafer 1312C can be triggered by an alert that a chloride gas concentration was a standard deviation (or more) lower than expected during an etch step. As a gas concentration can be expected to correlate to etch performance, a selection of effected production wafers for monitoring can be triggered.

The SEM metrology data 1316 is then compared to the pseudo-SEM performance indicators 1314C for the production wafer 1312C. A comparator 1318 can determine if the pseudo-SEM performance indicators 1314C correspond to the SEM metrology data 1316 to within a margin. The comparator 1318 can be an algorithm, model, program, processor, and/or controller which determines a comparison between inputs and determines if the inputs match or are equal to within a margin. The comparator 1318 can compare identical metrics (i.e., where a first input comprises metric A with value X and where the second input comprises metric A with value Y). The comparator 1318 can also compare disparate metrics but related metrics. For example, the comparator 1318 can compare a first input which is one or more SEM images to a second input which is one or more pseudo-SEM performance indicators. In the example, the SEM images can be compared to the one or more pseudo-SEM performance indicators by determining one or more SEM performance indicators for the SEM images and then comparing the one or more pseudo-SEM performance indicators and the one or more SEM performance indicators. Alternatively, the comparator 1318 can determine if the one or more pseudo-SEM performance indicators match the one or more SEM images or are consistent with possible values for the SEM performance indicators. The comparator 1318 can determine that the pseudo-SEM performance indicators 1314C match the SEM metrology data 1316 to within a margin and that the model 1308 is not to be retrained. In that case, the process 1310 can continue and the subsequent production wafer 1312D can be input into the model 1308. The comparator 1318 can determine that the pseudo-SEM performance indicators 1314C do not match the SEM metrology data 1316 to within a margin and that the model 1308 is to be retrained. One or more retraining wafers can be selected, including from the set of production wafers 1312A-1312D, and optical metrology data 1322 and SEM metrology data 1324 acquired to generate a retraining data set 1320. The model 1308 can then be retrained and/or updated based on the retraining set. Alternatively, a new model can be trained based on the retraining data set 1320. In some embodiments, the comparator 1318 can determine that the pseudo-SEM performance indicators 1314C may or may not match the SEM metrology data 1316 to within a margin and that additional SEM metrology data (for either the wafer under comparison or an additional one or more wafers) is to be acquired in order to make the comparison.

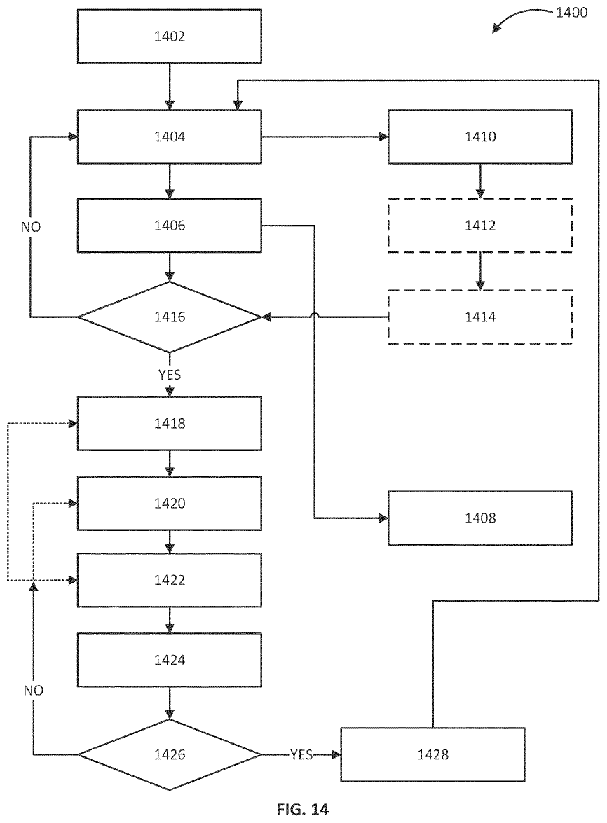

FIG. 14 illustrates an exemplary method 1400 for determination of feature parameters and, optionally, retraining of the model, according to some embodiments. Each of these operations is described in detail below. The operations of method 1400 presented below are intended to be illustrative. In some embodiments, method 1400 may be accomplished with one or more additional operations not described, and/or without one or more of the operations discussed. Additionally, the order in which the operations of method 1400 are illustrated in FIG. 14 and described below is not intended to be limiting. In some embodiments, one or more portions of method 1400 may be implemented (e.g., by simulation, modeling, etc.) in one or more processing devices (e.g., one or more processors). The one or more processing devices may include one or more devices executing some or all of the operations of method 1400 in response to instructions stored electronically on an electronic storage medium. The one or more processing devices may include one or more devices configured through hardware, firmware, and/or software to be specifically designed for execution of one or more of the operations of method 1400, for example.

At an operation 1402, a model trained to generate feature parameters for a production wafer based on optical metrology data is obtained. The model can be trained using any appropriate method, including those previously described. The model can be an algorithm or a function stored in one or more storage device and/or implemented by one or more processor. The model can output one or more feature parameter based on an input, where the input can be optical metrology data or one or more optical-metrology-derived performance indicators.

At an operation 1404, optical metrology data is obtained for one or more production wafer. The optical data can be obtained in an appropriate manner, such as previously described in reference to the operation 908 of FIG. 9. The optical metrology data can further comprise one or more optical-metrology-derived performance indicator. At an operation 1410, the one or more optical-metrology-derived performance indicators are monitored. Monitoring can comprise determining if the one or more optical-metrology-derived performance indicator are within an expected variation or range or if the one or more optical-metrology-derived performance indicators indicate that the process has changed or is not controlled. At an operation 1412, one or more fabrication performance indicators can optionally be monitored. The one or more fabrication performance indicators can be acquired from metrology data and/or fabrication controllers. The one or more fabrication performance indicator can be acquired and/or monitored asynchronously. At an operation 1414, one or more SEM-derived performance indicators are periodically monitored. Monitoring the one or more SEM-derived performance indicators can comprise acquiring SEM metrology data for one or more production wafer. The one or more SEM-derived performance indicators can be determined based on the SEM metrology data. The one or more SEM-derived performance indicators can be acquired asynchronously and periodically (including regularly or irregularly). Any of the operations 1410-1414 can generate a retraining trigger. Additionally, a retraining trigger can be generated by other operations not depicted.

At an operation 1406, feature parameters for the one or more production wafers are generated by the model based on the optical metrology data. The feature parameters can comprise one or more pseudo-SEM parameter. The feature parameters can comprise one or more SEM-derived performance indicator. The feature parameters can be user selected. The feature parameters depend on the training and type of the model. The model can also output one or more probability value and/or confidence interval for the feature parameters. The feature parameters of the production wafers can be output at an operation 1408. The operation 1408 can comprise storing the feature parameters and/or their values, or sending the feature parameters to one or more operation or controller for monitoring, updating, and controlling of the fabrication process.

At an operation 1416, it is determined if a retraining trigger has been detected. The retraining trigger can be generated by any one of the operations 1410-1414 or by other operations, including by a push button type trigger within the program itself. If a retraining trigger is not detected, flow continues to the operation 1404, where optical metrology data is acquired for one or more production wafer, and to the operation 1406, where feature parameters are generated for the production wafer by the model. If a retraining trigger is detected, flow continues to an operation 1418.

At an operation 1418, one or more retraining wafers are selected. The retraining wafers can be a subset of the production wafers. Alternatively, the retraining wafers may not be included in the production wafers. The retraining wafers are fabricated to the same process step as the training wafers used to train the model and as the production wafers upon which the model operates.

At an operation 1420, training data is obtained for the one or more retraining wafer. The training data can comprise optical metrology data and SEM metrology data. The training data can be acquired in an appropriate method, such as those described in reference to the operations 904 and 908 of FIG. 9.

At an operation 1422, the model is retrained based on the training data obtained at the operation 1420. The model can be retrained or have its training updated, such as through additional training on the training data of the operation 1420. Alternatively, a new model can be trained on the training data of the operation 1420. In some embodiments, whether the model is updated or replaced by a new model can depend on the type of retraining trigger detected or a magnitude of the difference between the model and one or more performance indicator which generated the retraining trigger. For example, the model may be updated if the retraining trigger indicates that a single pseudo-SEM parameter difference has exceeded a variance threshold. In another example, the model may be replaced is multiple pseudo-SEM parameters are out of margin. In yet another example, the model may be replaced by a new model if production is halted because of a power outage and/or a fab shutdown, where feature parameters after shutdown may not correlate to feature parameters before shutdown.

At an operation 1424, the retrained model is tested based on a set of testing data. Alternatively, the retrained model can be tested based on one or more wafer included in the retraining set or can be tested on areas of the retraining wafers not used in the training set of the operations 1420-1422. The retrained model can be tested for model accuracy. Testing the model may be omitted in some cases.

At an operation 1426, it is determined if the training criterion is satisfied. It can be determined if the training criterion is satisfied in any appropriate manner, including those described in relation to the operation 916 of FIG. 9. If the training criterion is not satisfied, the flow continues to one of the operations 1418, 1420, or 1422. The flow can continue to the operation 1418, where one or more additional retraining wafer is selected for inclusion in the training data. The flow can continue to the operation 1420, where additional training data is acquired for the one or more retraining wafers. The flow can continue to the operation 1422, where the model is further retrained on the training data of the operation 1420. Whether the flow continues to the operation 1418, 1420, or 1422 depends on the amount of training data available and the configuration of the specific program.

At an operation 1428, the retrained model is output. The model is output to generate feature parameters for production wafers. From the operation 1428, flow continues to the operation 1404, where optical metrology data is obtained for one or more production wafer.

As described above, method 1400 (and/or the other methods and systems described herein) is configured to provide a generic framework for determination of feature parameters and retraining of the model.

FIG. 15 depicts a schematic representation of measurement areas on a wafer, according to some embodiments. A wafer 1502, which has been fabricated at least partially, can comprise multiple measurement areas 1504A-1504C. Optical measurements can be restricted to sampling points which contain optical measurement structures-which can be one or more diffraction gratings. SEM measurements can occur at most positions on a wafer, but are limited by utility (i.e., some SEM images are not useful for determining feature parameters) and deleterious effects (some surfaces and/or materials experience damaged under SEM electron bombardment). The measurement area 1504A corresponds to an SEM image 1506A. The measurement area 1504B corresponds to an SEM image 1506B. The measurement area 1504C corresponds to an SEM image 1506C. The SEM images 1506A-1506C are pictographs for illustrative purposes only and should not be taken as limiting. The SEM images 1506A-1506C are not to scale and do not show correct pixel values. In the SEM images 1506A and 1506B, black bars 1510A-1510F represent lines corresponding to one or more diffraction grating. The SEM images 1506A and 1506B can also correspond to one or more pupil image 1508 obtained from diffraction. In the SEM images 1506A and 1506C, gray circles with white centers 1512A-1512H correspond to multi-level vias. The SEM image 1506A corresponds to an area for which optical measurements and SEM measurements can be performed. The SEM image 1506B corresponds to an area where optical measurement images can be performed, but where SEM measurements may not generate information about feature parameters. The SEM image 1506C corresponds to an area where SEM measurements can be performed. As optical measurements and SEM measurements measure different structures, areas in which optical measurements and SEM measurements are obtained can be semi-independent of each other and can be overlapping, partially overlapping, or nonoverlapping.

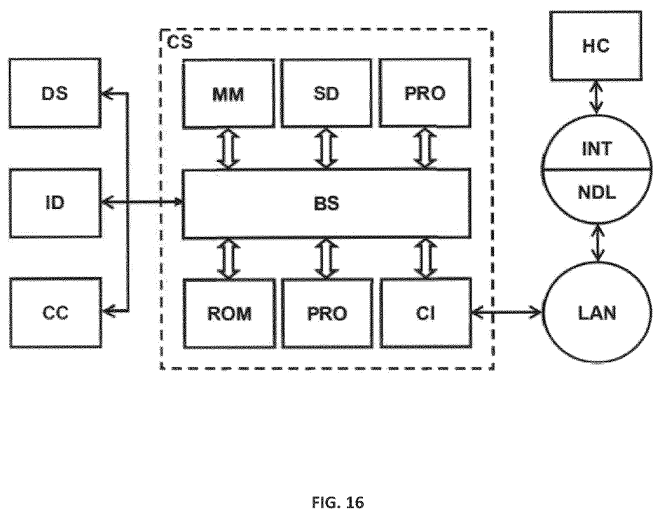

FIG. 16 is a diagram of an example computer system CS that may be used for one or more of the operations described herein. Computer system CS includes a bus BS or other communication mechanism for communicating information, and a processor PRO (or multiple processors) coupled with bus BS for processing information. Computer system CS also includes a main memory MM, such as a random-access memory (RAM) or other dynamic storage device, coupled to bus BS for storing information and instructions to be executed by processor PRO. Main memory MM also may be used for storing temporary variables or other intermediate information during execution of instructions by processor PRO. Computer system CS further includes a read only memory (ROM) ROM or other static storage device coupled to bus BS for storing static information and instructions for processor PRO. A storage device SD, such as a magnetic disk or optical disk, is provided and coupled to bus BS for storing information and instructions.

Computer system CS may be coupled via bus BS to a display DS, such as a cathode ray tube (CRT) or flat panel or touch panel display for displaying information to a computer user. An input device ID, including alphanumeric and other keys, is coupled to bus BS for communicating information and command selections to processor PRO. Another type of user input device is cursor control CC, such as a mouse, a trackball, or cursor direction keys for communicating direction information and command selections to processor PRO and for controlling cursor movement on display DS. This input device typically has two degrees of freedom in two axes, a first axis (e.g., x) and a second axis (e.g., y), that allows the device to specify positions in a plane. A touch panel (screen) display may also be used as an input device.

In some embodiments, portions of one or more methods described herein may be performed by computer system CS in response to processor PRO executing one or more sequences of one or more instructions contained in main memory MM. Such instructions may be read into main memory MM from another computer-readable medium, such as storage device SD. Execution of the sequences of instructions included in main memory MM causes processor PRO to perform the process steps (operations) described herein. One or more processors in a multi-processing arrangement may also be employed to execute the sequences of instructions contained in main memory MM. In some embodiments, hard-wired circuitry may be used in place of or in combination with software instructions. Thus, the description herein is not limited to any specific combination of hardware circuitry and software.

The term “computer-readable medium” and/or “machine readable medium” as used herein refers to any medium that participates in providing instructions to processor PRO for execution. Such a medium may take many forms, including but not limited to, non-volatile media, volatile media, and transmission media. Non-volatile media include, for example, optical or magnetic disks, such as storage device SD. Volatile media include dynamic memory, such as main memory MM. Transmission media include coaxial cables, copper wire and fiber optics, including the wires that comprise bus BS. Transmission media can also take the form of acoustic or light waves, such as those generated during radio frequency (RF) and infrared (IR) data communications. Computer-readable media can be non-transitory, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge. Non-transitory computer readable media can have instructions recorded thereon. The instructions, when executed by a computer, can implement any of the operations described herein. Transitory computer-readable media can include a carrier wave or other propagating electromagnetic signal, for example.

Various forms of computer readable media may be involved in carrying one or more sequences of one or more instructions to processor PRO for execution. For example, the instructions may initially be borne on a magnetic disk of a remote computer. The remote computer can load the instructions into its dynamic memory and send the instructions over a telephone line using a modem. A modem local to computer system CS can receive the data on the telephone line and use an infrared transmitter to convert the data to an infrared signal. An infrared detector coupled to bus BS can receive the data carried in the infrared signal and place the data on bus BS. Bus BS carries the data to main memory MM, from which processor PRO retrieves and executes the instructions. The instructions received by main memory MM may optionally be stored on storage device SD either before or after execution by processor PRO.

Computer system CS may also include a communication interface CI coupled to bus BS. Communication interface CI provides a two-way data communication coupling to a network link NDL that is connected to a local network LAN. For example, communication interface CI may be an integrated services digital network (ISDN) card or a modem to provide a data communication connection to a corresponding type of telephone line. As another example, communication interface CI may be a local area network (LAN) card to provide a data communication connection to a compatible LAN. Wireless links may also be implemented. In any such implementation, communication interface CI sends and receives electrical, electromagnetic, or optical signals that carry digital data streams representing various types of information.

Network link NDL typically provides data communication through one or more networks to other data devices. For example, network link NDL may provide a connection through local network LAN to a host computer HC. This can include data communication services provided through the worldwide packet data communication network, now commonly referred to as the “Internet” INT. Local network LAN (Internet) may use electrical, electromagnetic, or optical signals that carry digital data streams. The signals through the various networks and the signals on network data link NDL and through communication interface CI, which carry the digital data to and from computer system CS, are exemplary forms of carrier waves transporting the information.

Computer system CS can send messages and receive data, including program code, through the network(s), network data link NDL, and communication interface CL. In the Internet example, host computer HC might transmit a requested code for an application program through Internet INT, network data link NDL, local network LAN, and communication interface CI. One such downloaded application may provide all or part of a method described herein, for example. The received code may be executed by processor PRO as it is received, and/or stored in storage device SD, or other non-volatile storage for later execution. In this manner, computer system CS may obtain application code in the form of a carrier wave.

Further embodiments are described in below numbered clauses:
1. One or more non-transitory, machine-readable medium having instructions thereon, the instructions when executed by a processor being configured to perform operations comprising: obtaining scanning electron microscopy (SEM) metrology data for first areas on a training wafer; obtaining optical metrology data for second areas on the training wafer; and training a model, by using the SEM metrology data and the optical metrology data for the training wafer, to generate parameters for features on a production wafer based on optical metrology data for areas of the production wafer.
2. The one or more non-transitory, machine-readable medium of clause 1, further comprising: obtaining optical metrology data for areas of the production wafer; and determining feature parameters of the production wafer, based on the optical metrology data for the production wafer and the trained model.
3. The one or more non-transitory, machine-readable medium of clause 2, wherein the production wafer comprises a set of production wafers, wherein obtaining optical metrology data comprises obtaining optical metrology data for areas of the set of production wafers, and wherein determining feature parameters comprises determining feature parameters for the set of production wafers, based on the optical metrology data for the set of production wafers and the trained model.
4. The one or more non-transitory, machine-readable medium of any one of clauses 1 to 3, further comprising retraining the model based on detection of a retraining trigger.
5. The one or more non-transitory, machine-readable medium of clause 4, wherein detection of a retraining trigger comprises detecting a wafer fabrication change between the training and production wafers.
6. The one or more non-transitory, machine-readable medium of clause 5, wherein detecting the wafer fabrication change comprises: obtaining SEM metrology data for first areas on the production wafer; obtaining optical metrology data for second areas on the production wafer; generating, by the trained model, parameters for features on the production wafer based on the optical metrology data for the second areas on the production wafer; determining if the feature parameters of the production wafer match the SEM metrology data for the first areas of the production wafer; and based on a determination that the feature parameters for the production wafer do not match the SEM metrology data for the first areas of the production wafer, determining that a wafer fabrication change is detection.
7. The one or more non-transitory, machine-readable medium of clause 6, wherein determining if the feature parameters for the production wafer match the SEM metrology data for the first areas of the production wafer comprises determining if the feature parameters for the production wafer match the SEM metrology data for the first areas of the production wafer to within a threshold margin.
8. The one or more non-transitory, machine-readable medium of any one of clauses 4 to 7, wherein retraining the model comprises: obtaining SEM metrology data for first areas on a retraining wafer; obtaining optical metrology data for second areas on the retraining wafer; and training the model, by using the SEM metrology data for the first areas on the retraining wafer and the optical metrology data for the second areas on the retraining wafer, to generate parameters for features on modified production wafer based on optical metrology data for areas of the modified production wafer.
9. The one or more non-transitory, machine-readable medium of clause 8, wherein the retraining wafer comprises a set of retraining wafers, and wherein training the model comprises training the model by using the SEM metrology data for the first areas of the set of retraining wafers and the optical metrology data for the second areas on the set of retraining wafers.
10. The one or more non-transitory, machine-readable medium of clause 8 or 9, wherein the retraining wafer comprises the production wafer.
11. The one or more non-transitory, machine-readable medium of any one of clauses 5 to 10, wherein detecting the wafer fabrication change comprises monitoring one or more performance indicators associated with wafer fabrication.
12. The one or more non-transitory, machine-readable medium of claim 11, wherein monitoring the one or more performance indicators is conducted periodically.
13. The one or more non-transitory, machine-readable medium of clause 11 or 12, wherein the one or more performance indicators comprise at least one of an SEM-derived performance indicator, an optical-metrology-derived performance indicator, or a combination thereof.
14. The one or more non-transitory, machine-readable medium of any one of clauses 1 to 13, wherein obtaining SEM metrology data comprises determining one or more SEM-derived performance indicators and wherein training the model comprises training the model by using the one or more SEM-derived performance indicators and the optical metrology data.
15. The one or more non-transitory, machine-readable medium of clause 14, wherein the one or more SEM-derived performance indicators comprise at least one of one or more SEM measurement parameter, a relationship between a feature of an SEM image and the one or more SEM measurement parameter, or a combination thereof, wherein SEM measurement parameters comprise at least one of one or more edge location, one or more geometric image moment, one or more shape fitting dimension, one or more shape fitting orientation, one or more contour shape, one or more contour location, one or more material composition, or a combination thereof.
16. The one or more non-transitory, machine-readable medium of clause 14, wherein the one or more SEM-derived performance indicators comprise at least one of overlay, overlay error, critical dimension, critical dimension uniformity, edge placement error, focus, dose, local overlay, local overlay error, local critical dimension, local critical dimension uniformity, one or more feature dimension, or a combination thereof.
17. The one or more non-transitory, machine-readable medium of any one of clauses 14 to 16, wherein the one or more SEM-derived performance indicators are user selected.
18. The one or more non-transitory, machine-readable medium of any one of clauses 14 to 17, wherein the one or more SEM-derived performance indicators comprise the parameters for features on the training wafer.
19. The one or more non-transitory, machine-readable medium of any one of clauses 1 to 18, wherein obtaining optical metrology data comprises determining one or more optical-metrology-derived performance indicators and wherein training the model comprises training the model, by using the SEM metrology data and the one or more optical-metrology-derived performance indicators.
20. The one or more non-transitory, machine-readable medium of clause 19, wherein the one or more optical-metrology-derived performance indicators comprise at least one of total pupil average, inner pupil average, outer pupil average, total pupil variance, inner pupil variance, outer pupil variance, one or more lower-order Zernike coefficient, or a combination thereof.
21. The one or more non-transitory, machine-readable medium of clause 19 or 20, wherein the one or more optical-metrology-derived performance indicators is determined by a neural network, wherein the neural network operates upon optical metrology data.
22. The one or more non-transitory, machine-readable medium of any one of clauses 19 to 21, wherein the one or more optical-metrology-derived performance indicators are determined based on a pupil image.
23. The one or more non-transitory, machine-readable medium of any one of clauses 19 to 22, wherein the one or more optical-metrology-derived performance indicators comprise optical metrology performance indicators obtained for different wavelengths, different polarizations, or different wavelengths and different polarizations.
24. The one or more non-transitory, machine-readable medium of any one of clauses 19 to 23, wherein the one or more optical-metrology-derived performance indicators are user selected.
25. The one or more non-transitory, machine-readable medium of any one of clauses 1 to 24, wherein the features on the production wafer comprise at least one of lithographic features, etch features, implantation features, depositional features, multi-layer features, or a combination thereof.
26. The one or more non-transitory, machine-readable medium of any one of clauses 1 to 25, wherein the feature parameters comprise at least one of overlay, overlay error, critical dimension, critical dimension uniformity, edge placement error, focus, dose, local overlay, local overlay error, local critical dimension, local critical dimension uniformity, one or more feature dimension, or a combination thereof.
27. The one or more non-transitory, machine-readable medium of any one of clauses 1 to 26, wherein the production wafer is the training wafer and wherein training the model comprises training the model, by using the SEM metrology data for the first areas and the optical metrology data for the second areas, to generate parameters for features on the training wafer based on optical metrology data for third areas of the training wafer.
28. The one or more non-transitory, machine-readable medium of any one of clauses 1 to 27, wherein the training wafer comprises a set of training wafers and wherein training the model comprises training the model, by using the SEM metrology data for first areas on the set of training wafers and the optical metrology data for second areas on the set of training wafers, to generate parameters for features on a production wafer based on optical metrology data for areas of the production wafer.
29. The one or more non-transitory, machine-readable medium of any one of clauses 1 to 28, wherein the first areas on the training wafer and the second areas on the training wafer are non-overlapping.
30. The one or more non-transitory, machine-readable medium of any one of clauses 1 to 29, wherein the first areas on the training wafer and the second areas on the training wafer overlap at least in part.
31. The one or more non-transitory, machine-readable medium of any one of clauses 1 to 30, wherein the training wafer comprises the production wafer.
32. The one or more non-transitory, machine-readable medium of any one of clauses 1 to 31, wherein training the model further comprises: obtaining SEM metrology data for first areas on a test wafer; obtaining optical metrology data for second areas on the test wafer; generating, by the trained model, parameters for features of the test wafer based on optical metrology data for the second areas on the test wafer; and evaluating the trained model based on a relationship between the feature parameters of the test wafer and the SEM metrology data for first areas of the test wafer.
33. The one or more non-transitory, machine-readable medium of clause 32, wherein evaluating the trained model comprises determining if the feature parameters of the test wafer match the SEM metrology data for the first areas of the test wafer.
34. The one or more non-transitory, machine-readable medium of clause 33, further comprising: based on a determination that the feature parameters for the test wafer do not match the SEM metrology data for the first areas of the test wafer, further training the model.
35. The one or more non-transitory, machine-readable medium of clause 34, wherein further training the model comprises: obtaining SEM metrology data for third areas on the training wafer; obtaining optical metrology data for fourth areas on the training wafer; and training the model, by using the SEM metrology data for the first areas and the third areas on the training wafer and the optical metrology data for the second areas and the fourth areas on the training wafer, to generate parameters for features on the production wafer based on optical metrology data for areas of the production wafer.
36. The one or more non-transitory, machine-readable medium of clause 35, wherein the third areas on the training wafer comprise first areas on a second training wafer and wherein the fourth areas on the training wafer comprise second areas on the second training wafer.
37. The one or more non-transitory, machine-readable medium of any one of clauses 33 to 36 wherein determining if the feature parameters for the test wafer match the SEM metrology data for the first areas of the test wafer comprises determining if the feature parameters for the test wafer match the SEM metrology data for the first areas of the test wafer to within a threshold margin.
38. The one or more non-transitory, machine-readable medium of any one of clauses 32 to 37, wherein the test wafer is the training wafer and wherein the first areas of the test wafer comprise third areas on the training wafer and the second areas on the test wafer comprise fourth areas on the training wafer.
39. The one or more non-transitory, machine-readable medium of any one of clauses 32 to 38, wherein the test wafer comprises a set of test wafers, wherein generating parameters for features of the test wafer comprises generating parameters for features of the set of test wafers based on optical metrology data for the second areas on the set of test wafers, and wherein evaluating the trained model comprises evaluating the trained model based on a relationship between the feature parameters of the set of test wafers and the SEM metrology data for the first areas of the set of test wafers.
40. The one or more non-transitory, machine-readable medium of any one of clauses 32 to 39, wherein test wafer comprises the production wafer.
41. The one or more non-transitory, machine-readable medium of any one of clauses 1 to 40, parameters for features on the production wafer comprise at least one of geometric information for features on the production wafer, wafer process performance indicators, or a combination thereof.
42. The one or more non-transitory, machine-readable medium of any one of clauses 1 to 41, wherein the SEM metrology data and the optical metrology data correspond to a fabrication process step.
43. The one or more non-transitory, machine-readable medium of any one of clauses 1 to 42, wherein the model is a mathematical model.
44. The one or more non-transitory, machine-readable medium of any one of clauses 1 to 43, wherein the model is a regression model.
45. The one or more non-transitory, machine-readable medium of any one of clauses 1 to 44, wherein the model is a linear regression model.
46. The one or more non-transitory, machine-readable medium of any one of clauses 1 to 45, wherein the model is a machine learning model.
47. The one or more non-transitory, machine-readable medium of clause 46, wherein the machine learning model is at least one of a neural network model, a decision tree model, a random forest model, a support vector model, a k-nearest neighbor model, or a combination thereof.
48. One or more non-transitory, machine-readable medium having instructions thereon, the instructions when executed by a processor being configured to perform operations comprising: obtaining optical metrology data for areas of a production wafer; and determining parameters for features on the production wafer based on the optical metrology data and a trained model, wherein the parameters for features on the production wafer comprise pseudo-scanning electron-microscopy (SEM) parameters.
49. The one or more non-transitory, machine-readable medium of clause 48, wherein the pseudo-SEM parameters comprise parameters for features on the production wafer substantially similar to parameters acquired by SEM metrology.
50. The one or more non-transitory, machine-readable medium of clause 48 or 49, wherein the pseudo-SEM parameters are of at least one of higher resolution, higher accuracy, lower uncertainty, or a combination thereof than parameters derived from the optical metrology data.
51. The one or more non-transitory, machine-readable medium of any one of clauses 48 to 50, wherein the pseudo-SEM parameters comprise at least one parameter not derived from the optical metrology data.
52. The one or more non-transitory, machine-readable medium of any one of clauses 48 to 51, wherein the trained model is generated by: obtaining (SEM) metrology data for first areas on one or more training wafers; obtaining optical metrology data for second areas on the one or more training wafers; and training the model, by using the SEM metrology data and the optical metrology data, to generate parameters for features on the production wafer.
53. The one or more non-transitory, machine-readable medium of any one of clauses 48 to 52, wherein the feature parameters comprise at least one of overlay, overlay error, critical dimension, critical dimension uniformity, edge placement error, focus, dose, local overlay, local overlay error, local critical dimension, local critical dimension uniformity, one or more feature dimension, or a combination thereof.
54. The one or more non-transitory, machine-readable medium of any one of clauses 48 to 53, wherein obtaining optical metrology data further comprises determining optical metrology performance indicators for the areas of the production wafer based on the optical metrology data and wherein determining parameters comprises determining parameters for features on the production wafer based on the optical metrology performance indicators and the trained model.
55. The one or more non-transitory, machine-readable medium of clause 54, wherein the optical metrology performance indicators are determined based on pupil images.
56. The one or more non-transitory, machine-readable medium of clause 54, wherein the optical metrology performance indicators comprise one or more of total pupil average, inner pupil average, outer pupil average, total pupil variance, inner pupil variance, outer pupil variance, one or more lower-order Zernike coefficient, or a combination thereof.
57. The one or more non-transitory, machine-readable medium of any one of clauses 54 to 56, wherein the optical metrology performance indicators are determined based on measurements taken at multiple wavelengths, multiple polarizations, or multiple wavelength and multiple polarizations.
58. The one or more non-transitory, machine-readable medium of any one of clauses 48 to 57, further comprising: obtaining optical metrology data for areas of a second production wafer; and determining parameters for features on the second production wafer based on the optical metrology data of the second production wafer and the trained model.
59. The one or more non-transitory, machine-readable medium of any one of clauses 48 to 58, wherein the production wafer comprises a set of production wafers and wherein determining parameters for features comprises determining parameters for features on the set of production wafers based on the optical metrology data for the set of production wafers and the trained model.
60. One or more non-transitory, machine-readable medium having instructions thereon, the instructions when executed by a processor being configured to perform operations comprising: obtaining optical metrology data for areas of a production wafer; determining pseudo-scanning electron-microscopy (SEM) parameters for the production wafer based on the optical metrology data and a model, wherein the model relates pseudo-SEM parameters to optical metrology data; and determining one or more fabrication parameters for the production wafer based on the pseudo-SEM parameters.
61. The one or more non-transitory, machine-readable medium of clause 60, further comprising: controlling one or more fabrication processes based on the one or more fabrication parameters.
62. A system comprising: a processor; and one or more non-transitory, machine-readable medium as described in any of clauses 1 to 61.
63. A method comprising: obtaining scanning electron microscopy (SEM) metrology data for first areas on one or more training wafers; obtaining optical metrology data for second areas on the one or more training wafers; and training a model, by using the SEM metrology data and the optical metrology data, to generate parameters for features on one or more production wafers based on optical metrology data for areas of the one or more production wafers.
64. The method of clause 63, further comprising: obtaining optical metrology data for areas of the one or more production wafers; and determining parameters for features on the one or more production wafers, based on the optical metrology data for the one or more production wafers and the trained model.
65. The method of clause 63 or 64, wherein the one or more production wafers comprises one or more of the one or more training wafers.

The concepts disclosed herein may simulate or mathematically model any generic imaging, etching, polishing, inspection, etc. system for sub wavelength features, and may be useful with emerging imaging technologies capable of producing increasingly shorter wavelengths. Emerging technologies include EUV (extreme ultraviolet), DUV lithography that is capable of producing a 193 nm wavelength with the use of an ArF laser, and even a 157 nm wavelength with the use of a Fluorine laser. Moreover, EUV lithography is capable of producing wavelengths within a range of 20-50 nm by using a synchrotron or by hitting a material (either solid or a plasma) with high energy electrons in order to produce photons within this range.

While the concepts disclosed herein may be used for manufacturing with a substrate such as a silicon wafer, it shall be understood that the disclosed concepts may be used with any type of manufacturing system (e.g., those used for manufacturing on substrates other than silicon wafers).

In addition, the combination and sub-combinations of disclosed elements may comprise separate embodiments. For example, one or more of the operations described above may be included in separate embodiments, or they may be included together in the same embodiment.

The descriptions above are intended to be illustrative, not limiting. Thus, it will be apparent to one skilled in the art that modifications may be made as described without departing from the scope of the claims set out below.

1. One or more non-transitory, machine-readable medium having instructions thereon, the instructions when executed by one or more processors of a system being configured to cause the system to perform operations comprising:
obtaining scanning electron microscopy (SEM) metrology data for first areas on a training wafer;
obtaining optical metrology data for second areas on the training wafer; and
training a model, by using the SEM metrology data and the optical metrology data for the training wafer, to generate parameters for features on a production wafer based on optical metrology data for areas of the production wafer.

2. The one or more non-transitory, machine-readable medium of claim 1, wherein the operations further comprise:
obtaining optical metrology data for areas of the production wafer; and
determining feature parameters of the production wafer, based on the optical metrology data for the production wafer and the trained model.

3. The one or more non-transitory, machine-readable medium of claim 2, wherein the production wafer comprises a set of production wafers, wherein obtaining optical metrology data comprises obtaining optical metrology data for areas of the set of production wafers, and wherein determining feature parameters comprises determining feature parameters for the set of production wafers, based on the optical metrology data for the set of production wafers and the trained model.

4. The one or more non-transitory, machine-readable medium of claim 1, wherein the operations further comprise retraining the model based on detection of a retraining trigger.

5. The one or more non-transitory, machine-readable medium of claim 4, wherein detection of a retraining trigger comprises detecting a wafer fabrication change between the training and production wafers.

6. The one or more non-transitory, machine-readable medium of claim 5, wherein detecting the wafer fabrication change comprises:
obtaining SEM metrology data for first areas on the production wafer;
obtaining optical metrology data for second areas on the production wafer;
generating, by the trained model, parameters for features on the production wafer based on the optical metrology data for the second areas on the production wafer;
determining if the feature parameters of the production wafer match the SEM metrology data for the first areas of the production wafer; and
based on a determination that the feature parameters for the production wafer do not match the SEM metrology data for the first areas of the production wafer, determining that a wafer fabrication change is detection.

7. The one or more non-transitory, machine-readable medium of claim 6, wherein determining if the feature parameters for the production wafer match the SEM metrology data for the first areas of the production wafer comprises determining if the feature parameters for the production wafer match the SEM metrology data for the first areas of the production wafer to within a threshold margin.

8. The one or more non-transitory, machine-readable medium of claim 4, wherein retraining the model comprises:
obtaining SEM metrology data for first areas on a retraining wafer;
obtaining optical metrology data for second areas on the retraining wafer; and
training the model, by using the SEM metrology data for the first areas on the retraining wafer and the optical metrology data for the second areas on the retraining wafer, to generate parameters for features on modified production wafer based on optical metrology data for areas of the modified production wafer.

9. The one or more non-transitory, machine-readable medium of claim 8, wherein the retraining wafer comprises a set of retraining wafers, and wherein training the model comprises training the model by using the SEM metrology data for the first areas of the set of retraining wafers and the optical metrology data for the second areas on the set of retraining wafers.

10. The one or more non-transitory, machine-readable medium of claim 8, wherein the retraining wafer comprises the production wafer.

11. The one or more non-transitory, machine-readable medium of claim 5, wherein detecting the wafer fabrication change comprises monitoring one or more performance indicators associated with wafer fabrication.

12. The one or more non-transitory, machine-readable medium of claim 11, wherein monitoring the one or more performance indicators is conducted periodically.

13. The one or more non-transitory, machine-readable medium of claim 11, wherein the one or more performance indicators comprise at least one of an SEM-derived performance indicator, an optical-metrology-derived performance indicator, or a combination thereof.

14. The one or more non-transitory, machine-readable medium of claim 1, wherein obtaining SEM metrology data comprises determining one or more SEM-derived performance indicators and wherein training the model comprises training the model by using the one or more SEM-derived performance indicators and the optical metrology data.

15. The one or more non-transitory, machine-readable medium of claim 14, wherein the one or more SEM-derived performance indicators comprise at least one of one or more SEM measurement parameter, a relationship between a feature of an SEM image and the one or more SEM measurement parameter, or a combination thereof, wherein SEM measurement parameters comprise at least one of one or more edge location, one or more geometric image moment, one or more shape fitting dimension, one or more shape fitting orientation, one or more contour shape, one or more contour location, one or more material composition, or a combination thereof.

16. The one or more non-transitory, machine-readable medium of claim 14, wherein the one or more SEM-derived performance indicators comprise at least one of overlay, overlay error, critical dimension, critical dimension uniformity, edge placement error, focus, dose, local overlay, local overlay error, local critical dimension, local critical dimension uniformity, one or more feature dimension, or a combination thereof.

17. The one or more non-transitory, machine-readable medium of claim 14, wherein the one or more SEM-derived performance indicators are user selected.

18. A method comprising:
obtaining scanning electron microscopy (SEM) metrology data for first areas on one or more training wafers;
obtaining optical metrology data for second areas on the one or more training wafers; and
training a model, by using the SEM metrology data and the optical metrology data, to generate parameters for features on one or more production wafers based on optical metrology data for areas of the one or more production wafers.

19. The method of claim 18, further comprising: obtaining optical metrology data for areas of the one or more production wafers; and determining parameters for features on the one or more production wafers, based on the optical metrology data for the one or more production wafers and the trained model.

20. The method of claim 18, wherein the one or more production wafers comprises one or more of the one or more training wafers.
